(19) United States
(12) Patent Application Publication
(10) Pub. No.: US 2023/0037301 A1
(43) Pub. Date: Feb. 9, 2023

(54) NEGATIVE PHOTOSENSITIVE RESIN COMPOSITION, PATTERN STRUCTURE AND METHOD FOR PRODUCING PATTERNED CURED FILM

(71) Applicant: CENTRAL GLASS COMPANY, LIMITED, Ube-shi (JP)

(72) Inventors: Takashi MASUBUCHI, Saitama (JP); Yuri OIKAWA, Saitama (JP); Kazuhiro YAMANAKA, Yamaguchi (JP); Rikako YOTSUMOTO, Saitama (JP)

(21) Appl. No.: 17/945,742

(22) Filed: Sep. 15, 2022

Related U.S. Application Data
(63) Continuation of application No. PCT/JP2021/009868, filed on Mar. 11, 2021.

(30) Foreign Application Priority Data
Mar. 16, 2020 (JP) 2020-045832
Apr. 22, 2022 (JP) 2020-076296

(51) Int. Cl. G03F 7/038; G03F 7/004; G03F 7/32; G03F 7/38

(52) U.S. Cl. CPC G03F 7/0382; G03F 7/0048; G03F 7/322; G03F 7/38

(57) ABSTRACT

A new photosensitive resin composition based on a polysiloxane, that is, a negative photosensitive resin composition is provided. A negative photosensitive resin composition includes (A) a polysiloxane compound containing a first structural unit represented by the following general formula (1), (B) a photoinduced curing accelerator, and (C) a solvent.

[(R^{x})_{b}R¹ₘSiO_{n/2}] (1)

### CROSS-REFERENCE TO RELATED APPLICATIONS

This application is a Continuation of International Patent Application No. PCT/JP2021/009868, filed on Mar. 11, 2021, which claims the benefit of priority to Japanese Patent Application No. 2020-045832, filed on Mar. 16, 2020, and Japanese Patent Application No. 2020-076296, filed on Apr. 22, 2020, the entire contents of which are incorporated herein by reference.

### FIELD

The present disclosure relates to a negative photosensitive resin composition, a pattern structure composed thereof, and a method for producing a patterned cured film.

### BACKGROUND

Polymer compounds containing a siloxane bonding (hereinafter sometimes referred to as polysiloxane) take advantage of their high heat resistance and transparency, and are used as coating materials for liquid crystal displays and organic EL displays, coating materials for image sensors, and sealing materials in semiconductor fields. It is also used as hard mask materials for multilayer resists because it has high oxygen plasma resistance. In order to use polysiloxane as a photosensitive material capable of patterning, it is required to be soluble in an alkaline aqueous solution such as an alkaline developer. Examples of the means for making the polysiloxane soluble in the alkaline developer include the use of a silanol group in the polysiloxane and the introduction of an acidic group into the polysiloxane. Examples of such an acidic group include a phenol group, a carboxyl group, a fluorocarbinolyl group and the like.

Japanese laid-open patent publication No. 2012-242600 discloses a polysiloxane in which a silanol group is used as a soluble group in an alkaline developer. On the other hand, the polysiloxane having a phenol group is disclosed in Japanese laid-open patent publication No. H4-130324, the polysiloxane having a carboxyl group is disclosed in Japanese laid-open patent publication No. 2005-330488, and the hexafluoroisopropanol group (2-hydroxy-1,1,1,3,3,3-hexafluoroisopropyl group [—C(CF3)₂OH]) is disclosed in Japanese laid-open patent publication No. 2015-129908, respectively. These polysiloxanes can be used as a positive resist composition by combining with a photoacid generator or a photosensitive compound having a quinonediazide group.

A polysiloxane having a hexafluoroisopropanol group (2-hydroxy-1,1,1,3,3,3-hexafluoroisopropyl group [—C(CF3)₂OH]) disclosed in Japanese laid-open patent publication No. 2015-129908 relating to a positive resist composition has good transparency, heat resistance, and acid resistance, and a pattern structure based on the polysiloxane is promising as a permanent structure in various elements.

### SUMMARY

An object of the present invention is to provide a new photosensitive resin composition based on the above polysiloxane, that is, a negative photosensitive resin composition.

As a result of diligent studies to solve the above problems, the present inventors have found a negative photosensitive resin composition including:

(A) a polysiloxane compound containing a first structural unit represented by the following general formula (1);

(B) a photoinduced curing accelerator; and

(C) a solvent.

[(R^{x})_{b}R¹ₘSiO_{n/2}] (1)

In the general formula (1), R^{x} is a monovalent group represented by the following general formula (1a),

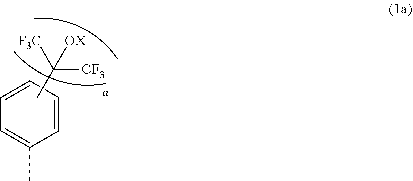

R¹ is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms,

b is a number of 1 or more and 3 or less, m is a number of 0 or more and less than 3, n is a number of more than 0 and 3 or less, b+m+n=4,

when there are a plurality of R^{x} and R¹, R^{x} and R¹ are independently selected from any of the substituents described above, and

in the general formula (1a), X is a hydrogen atom, a is a number of 1 or more and 5 or less, and a broken line represents a bond.

Japanese laid-open patent publication No. 2015-129908 discloses a positive photosensitive resin composition containing a polysiloxane compound containing the first structural unit represented by the above general formula (1) and a quinonediazide compound as constituent components, or a positive photosensitive resin composition containing a polysiloxane compound component in which a hydroxyl group of a polysiloxane compound containing the first structural unit represented by the above general formula (1) is protected by an acid instability group and a photoacid generator as components. On the other hand, the present negative photosensitive resin composition can realize a negative photosensitive resin composition by adding (B) a photoinduced curing accelerator (photoacid generator and a photobase generator, etc.) to a polysiloxane compound containing the first structural unit represented by the above (A) general formula (1), unlike Japanese laid-open patent publication No. 2015-129908.

Further, it was found that the patterned cured film obtained by the negative photosensitive resin composition is a material having excellent heat resistance and transparency.

### BRIEF DESCRIPTION OF DRAWINGS

FIG. 1 is a schematic diagram explaining a producing method of a patterned cured film 100 according to one embodiment of the invention.

FIG. 2 is a schematic diagram of a patterned structure 200 according to one embodiment of the invention.

### DESCRIPTION OF EMBODIMENT

Hereinafter, a negative photosensitive resin composition, a pattern structure, and a method for producing a patterned cured film according to one embodiment of the present invention will be described. However, the embodiments of the present invention are not construed as being limited to the contents described in the embodiments and examples shown below. In the present specification, the expression “X to Y” in the description of the numerical range shall indicate X or more and Y or less unless otherwise specified.

The negative photosensitive resin composition according to the embodiment of the present invention contains the following components (A) to (C).

(A) Polysiloxane compound containing the first structural unit represented by the following general formula (1)

(B) Photoinduced curing accelerator

(C) Solvent

[(R^{x})_{b}R¹ₘSiO_{n/2}] (1)

In the general formula (1), R^{x} is a monovalent group represented by the following general formula (1a).

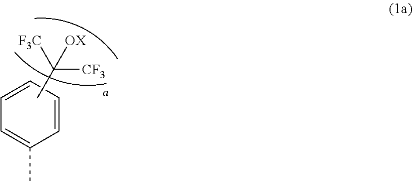

R¹ is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms,

b is a number of 1 or more and 3 or less, m is a number of 0 or more and less than 3, n is a number of more than 0 and 3 or less, and b+m+n=4,

when there are a plurality of R^{x} and R¹, R^{x} and R¹ are independently selected from any of the substituents described above.

In the general formula (1a), X is a hydrogen atom, a is a number of 1 or more and 5 or less, and a broken line represents a bond.

Here, in the first structural unit represented by the general formula (1), b, m and n are theoretical values of b being an integer of 1 to 3, m being an integer of 0 to 3, and n being an integer of 0 to 3. Further, b+m+n=4 means that the total of the theoretical values is 4. However, for example, in the values obtained by a ²⁹Si NMR measurement, b, m and n are obtained as average values, respectively. Therefore, b of the average value may be a decimal number rounded to 1 or more and 3 or less, m may be a decimal number rounded to 0 or more and 3 or less (however, m <3.0), and n may be a decimal number rounded to 0 or more and 3 or less (where n≠0). The theoretical value n=0 indicates that the structural unit is a monomer, and the average value n≠0 indicates that all of the compounds are not monomers. Therefore, the term that n is an integer of 0 to 3 as a theoretical value, and n is a decimal number that is rounded to 0 or more and 3 or less (however, n≠0) as a value obtained by a ²⁹Si NMR measurement shows that the siloxane compound may contain a monomer, but does not show that all of the siloxane compound is a monomer.

Further, in the monovalent group represented by the general formula (1a), a is an integer of 1 or more and 5 or less as a theoretical value. However, the value obtained by for example a ²⁹Si NMR measurement may be a decimal number rounded to 1 or more and 5 or less.

In the negative photosensitive resin composition, (A) the polysiloxane compound preferably includes a second structural unit represented by the following general formula (2) and/or a third structural unit represented by the following general formula (3).

[(R^{y})_{c}R²ₚSiO_{q/2}] (2)

[(R^{W})ₜSiO_{u/2}] (3)

In the general formula (2), R^{y} is a substituent selected from monovalent organic groups having 1 to 30 carbon atoms including any of an epoxy group, an oxetane group, an acryloyl group, a methacryloyl group, and a lactone group.

R² is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms.

C is a number of 1 or more and 3 or less, p is a number of 0 or more and less than 3, q is a number of more than 0 and 3 or less, and c+p+q=4.

When there are a plurality of R^{y} and R², R^{y} and R² are independently selected from any of the substituents described above.

In the general formula (3), R^{W} is a substituent selected from the group consisting of a halogen group, an alkoxy group, and a hydroxy group.

t is a number of 0 or more and less than 4, u is a number more than 0 and 4 or less, and t+u=4.

Here, in the second structural unit represented by the general formula (2), c, p, and q are theoretical values of c being an integer of 1 to 3, p being an integer of 0 to 3, and q being an integer of 0 to 3. Further, c+p+q=4 means that the total theoretical value is 4. However, for example, in the values obtained by a ²⁹Si NMR measurement, c, p and q are obtained as average values, therefore c of the average value may be a decimal number rounded to 1 or more and 3 or less, and p of the average value may be a decimal number rounded to 0 or more and 3 or less (however, p<3.0) and q of the average value may be a decimal number rounded to 0 or more and 3 or less (where q≠0).

Further, in the third structural unit represented by the general formula (3), t and u are theoretical values of t being an integer of 0 to 4 and u being an integer of 0 to 4. Further, t+u=4 means that the total theoretical value is 4. However, for example, in the value obtained by a ²⁹Si NMR measurement, t and u are obtained as average values, respectively, therefore t of the average value may be a decimal number rounded to 0 or more and 4 or less (however, t<4.0), u may be a decimal number rounded to 0 or more and 4 or less (however u≠0).

The polysiloxane compound containing the first structural unit represented by the general formula (1) has a hydroxyl group of hexafluoroisopropanol (HFIP) group. The negative photosensitive resin composition is exposed through a photomask after film formation to promote a silanol condensation reaction with an acid or base generated from a photoinduced curing accelerator, that is, a solgel polymerization reaction in the exposed part. Therefore, it is possible to reduce the dissolution rate in the alkaline developer, that is, to realize the resistance to the alkaline developer. On the other hand, it is considered that the unexposed portion does not have the effect of promoting the polymerization reaction, and the effect of the HFIP group causes dissolution in the alkaline developer, resulting in the formation of a negative pattern. Further, the epoxy group, oxetane group, acryloyl group, and methacryloyl group in the general formula (2) are also considered to contribute to the formation of a negative pattern by a cross-linking reaction in the exposed portion.

O_{n/2} in the general formula (1) is generally used as an expression for a polysiloxane compound. The following formula (1-1) represents that n is 1, the formula (1-2) represents that n is 2, and formula (1-3) represents that n is 3. When n is 1, it is located at the end of the polysiloxane chain in the polysiloxane compound.

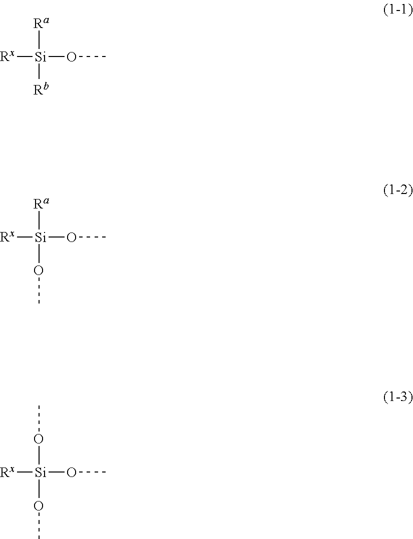

In the general formulas (1-1) to (1-3), R^{x} is synonymous with R^{x} in the general formula (1), and R^{a} and R^{b} are independently synonymous with R^{x} and R1 in the general formula (1). The broken line represents a bond with another Si atom.

O_{q/2} in the general formula (2), is the same as above, the following general formula (2-1) represents that q is 1, the general formula (2-2) represents that q is 2, and the general formula (2-3) represents that q is 3. When q is 1, it is located at the end of the polysiloxane chain in the polysiloxane compound.

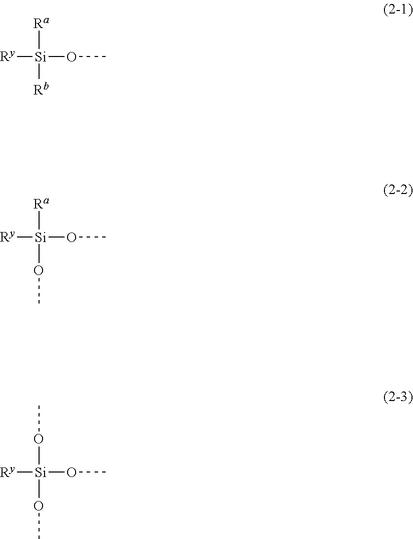

In the general formula, R^{y} is synonymous with R^{y} in the general formula (2), and R^{a} and R^{b} are independently synonymous with R^{y} and R² in the general formula (2). The broken line represents a bond with another Si atom.

Regarding O_{u/2} in the general formula (3), O_{4/2} when u=4 represents the following general formula (3-1). In the general formula (3-1), the broken line represents a bond with another Si atom.

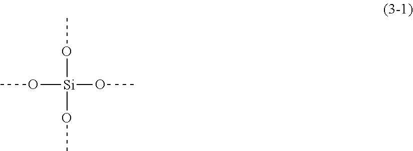

O_{4/2} in the above general formula (3) is generally called a Q4 unit, and shows a structure in which all four bonds of Si atoms form a siloxane bonding. Although Q4 has been described above, the general formula (3) may include a hydrolyzable/condensable group in the bond, such as the Q0, Q1, Q2, and Q3 units shown below. Further, the general formula (3) may have at least one selected from the group consisting of Q1 to Q4 units.

Q0 unit: A structure in which all four bonds of the Si atom are hydrolyzable/condensable groups (groups capable of forming a siloxane bonding, such as a halogen group, an alkoxy group, or a hydroxy group).

Q1 unit: A structure in which one of the four bonds of the Si atom forms a siloxane bonding and the remaining three are all hydrolyzable/polycondensable groups.

Q2 unit: A structure in which two of the four Si atom bonds form a siloxane bonding, and the remaining two are all hydrolyzable/polycondensable groups.

Q3 unit: A structure in which three of the four bonds of the Si atom form a siloxane bonding and the remaining one is the above-mentioned hydrolyzable/polycondensable group.

Hereinafter, the structural units represented by the general formula (1), the general formula (2), and the general formula (3) of the (A) polysiloxane compound will be described in order.

### [First Structural Unit Represented by the General Formula (1)]

[(R^{x})_{b}R¹ₘSiO_{n/2}] (1)

In the general formula (1), R¹ is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms.

b is a number of 1 or more and 3 or less, m is a number of 0 or more and less than 3, n is a number of more than 0 and 3 or less, and b+m+n=4.

When there are a plurality of R^{x} and R¹, R^{x} and R¹ are independently selected from any of the substituents described above.

In the general formula (1), R^{x} is a monovalent group represented by the following general formula (1a).

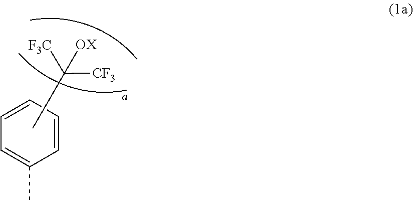

In the general formula (1a), X is a hydrogen atom, a is a number of 1 or more and 5 or less, and a broken line represents a bond.

In the general formula (1), as R¹, a hydrogen atom, a methyl group, an ethyl group, a 3,3,3-trifluoropropyl group, and a phenyl group can be specifically exemplified. In the theoretical values of b, m, and n, b is preferably an integer of 1 or 2. m is preferably an integer of 0 or more and 2 or less, and more preferably an integer of 0 or 1. n is preferably an integer of 1 or more and 3 or less, and more preferably an integer of 2 or 3. a is preferably 1 or 2.

Further, b is preferably a number of 1 or more and 2 or less. m is preferably a number of 0 or more and 2 or less, and more preferably 0 or more and 1 or less. n is preferably a number of 1 or more and 3 or less, and more preferably 2 or more and 3 or less.

Above all, from the viewpoint of ease of production, the number of HFIP group containing aryl groups represented by the general formula (1a) in the general formula (1) is preferably one. That is, the structural unit in which b is 1 is an example of a particularly preferable structural unit of the general formula (1).

As the group represented by the general formula (1a) in the general formula (1), any of the groups represented by the general formulas (1aa) to (1 ad) is particularly preferable.

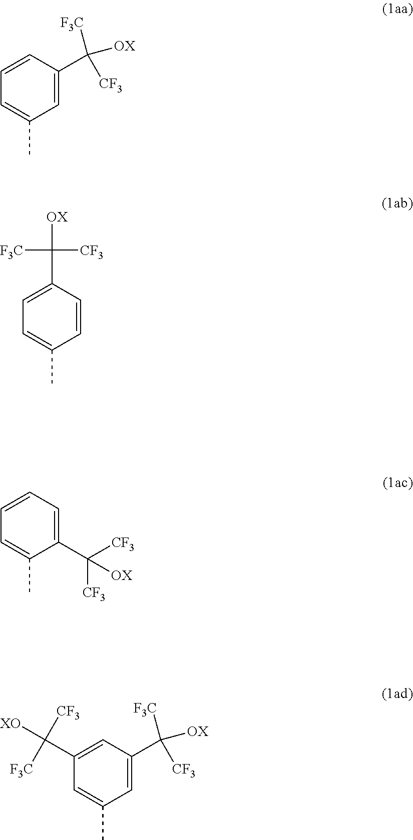

In the general formulas (1aa) to (1 ad), the broken line represents a bond.

In one embodiment, the first structural units represented by the general formula (1) preferably consists of a single structural unit. Here, “consisting of a single structural unit” means that it is composed of a structural unit in which the number of a, the number of b, the substituent species of R¹ (excluding hydroxy groups and alkoxy groups) and the number m of R¹ in the general formula (1) (however, excluding the number of hydroxy groups and alkoxy groups in m) are the same between the first structural units.

Further, in one embodiment of the negative photosensitive resin composition, with respect to a weight average molecular weight (Mw₁) of the negative photosensitive resin composition and a weight average molecular weight (Mw₂) of a film obtained by applying the negative photosensitive resin composition to a substrate and exposing with light of 365 nm at 560 mJ/cm² and heating at 100° C. for 1 minute to cure, a molecular weight increase rate represented by (Mw₂-Mw₁)/Mw₁ is preferably 0.50 or more. The upper limit is not particularly limited, but may be, for example, 70 or less. A large weight average molecular weight is preferable because chemical resistance and heat resistance can be improved.

### [Second Structural Unit Represented by the General Formula (2)]

[(R^{y})_{c}R²ₚSiO_{q/2}] (2)

In the general formula (2), R^{y} is a substituent selected from monovalent organic groups having 1 to 30 carbon atoms including any of an epoxy group, an oxetane group, an acryloyl group, a methacryloyl group, and a lactone group.

R² is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms.

c is a number of 1 or more and 3 or less, p is a number of 0 or more and less than 3, q is a number of more than 0 and 3 or less, and c+p+q=4.

When there are a plurality of R^{y} and R², R^{y} and R² are independently selected from any of the substituents described above.

In the theoretical values of c, p, and q of the general formula (2), p is preferably an integer of 0 or more and 2 or less, and more preferably an integer of 0 or 1. q is preferably an integer of 1 or more and 3 or less, and more preferably an integer of 2 or 3. Further, from the viewpoint of availability, the value of c is particularly preferably 1. Among these, the structural unit in which c is 1, p is 0, and q is 3, is an example of a particularly preferable structural unit of the general formula (2). Specific examples of R² include a hydrogen atom, a methyl group, an ethyl group, a phenyl group, a methoxy group, an ethoxy group, and a propoxy group.

Further, c is preferably a number of 1 or more and 2 or less, and more preferably 1. p is preferably a number of 0 or more and 2 or less, and more preferably 0 or more and 1 or less. q is preferably a number of 1 or more and 3 or less, and more preferably 2 or more and 3 or less.

When the R^{y} group of the second structural unit represented by the general formula (2) is a substituent having any of an epoxy group, an oxetane group, or a lactone group, it is possible to impart good adhesion to various substrates having silicon, glass, resin or the like on the contact surface with the film to the pattern cured film obtained from the negative photosensitive resin composition. When the R^{y} group is a substituent having an acryloyl group or a methacryloyl group, a highly curable film can be obtained and good solvent resistance can be obtained. Further, when the negative photosensitive resin composition has a photoacid generator and/or a photobase generator, in the heat treatment (fourth step described later) for obtaining the patterned cured film, condensation and a curing reaction easily proceed at a relatively low heating temperature and a good cured film can be preferably obtained. In particular, when the R^{y} group is a substituent having any one of an epoxy group, an acryloyl group, or a methacryloyl group, the above temperature can be lowered (for example, 200° C. or lower), which is preferable.

When the R^{y} group is a substituent containing an epoxy group and an oxetane group, the R^{y} group is preferably a group represented by the following general formulas (2a), (2b) and (2c).

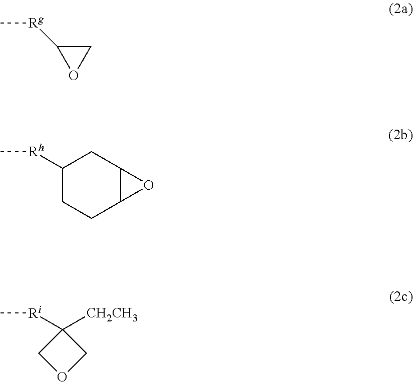

In the general formulas (2a), (2b) and (2c), R^{g}, R^{h} and Rⁱ each independently represent a divalent linking group. The dashed line represents the bond.

Here, when R^{g}, R^{h} and Rⁱ are divalent linking groups, examples of the divalent linking group include an alkylene group having 1 to 20 carbon atoms, and it may contain one or more sites forming an ether bond. When the number of carbon atoms is 3 or more, the alkylene group may be branched, or distant carbon atoms may be connected to form a ring. When there are two or more alkylene groups, one or more sites forming an ether bond may be contained by inserting oxygen between carbon atoms, and these are preferred examples as the divalent linking group.

Of the second structural units represented by the general formula (2), a particularly preferable one is represented by alkoxysilane as a raw material, 3-glycidoxypropyltrimethoxysilane (manufactured by Shin-Etsu Chemical Co., Ltd., product name: KBM-403), 3-glycidoxypropyltriethoxysilane (same as above, product name: KBE-403), 3-glycidoxypropylmethyldiethoxysilane (same as above, product name: KBE-402), 3-glycydoxypropylmethyldimethoxysilane (same as above, product name: KBM-402), 2-(3,4-epoxycyclohexyl) ethyltrimethoxysilane (same as above, product name: KBM-303), 2-(3,4-epylcyclohexyl) ethyltriethoxysilane, 8-glycidoxyoctyltrimethoxysilane (same as above, product name: KBM-4803), [(3-ethyl-3-oxetanyl) methoxy] propyltrimethoxysilane, [(3-ethyl)-3-oxetanyl) methoxy] propyltriethoxysilane and the like.

When the R^{y} group is a substituent having an acryloyl group or a methacryloyl group, it is preferably a group selected from the following general formula (3a) or (4a).

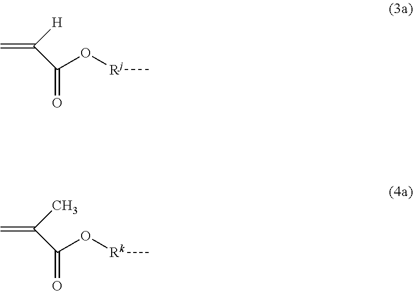

In the general formula (3a) or (4a), R^{j} and R^{k} each independently represent a divalent linking group. The dashed line represents the bond.

Preferred examples of cases where R^{j} and R^{k} are divalent linking groups can again include those listed as preferred groups for R^{g}, R^{h}, Rⁱ, R^{j} and R^{k}.

Of the second structural units represented by the general formula (2), a particularly preferable one is exemplified by alkoxysilane as a raw material, 3-methacryloxypropyltrimethoxysilane (manufactured by Shin-Etsu Chemical Co., Ltd., product name: KBM-503), 3-methacryloxypropyltriethoxysilane (same as above, product name: KBE-503), 3-methacryloxypropylmethyldimethoxysilane (same as above, product name: KBM-502), 3-methacryloxypropylmethyldiethoxysilane (same as above, product name: KBE-502) 3-acryloxypropyltrimethoxysilane (same as above, product name: KBM-5103), 8-methacryloxyoctyltrimethoxysilane (same as above, product name: KBM-5803) and the like.

Further, in the examples described later, it was found that the negative photosensitive resin composition containing an acrylate-modified product or a methacrylate-modified product in which the R^{y} group is a substituent having an acryloyl group or a methacryloyl group can obtain a good cured film even by heat treatment at a relatively low temperature of about 150° C. to 160° C. in the fourth step described later. From the above points, when treatment at a low temperature is desired, a negative photosensitive resin composition in which the R^{y} group has an acryloyl group or a methacryloyl group can be preferably used. In the present specification, the “low temperature” may be, for example, a temperature of 200° C. or lower, preferably 180° C. or lower, and more preferably 160° C. or lower.

When the R^{y} group is a substituent having a lactone group, the group is preferably a group selected from the following formulas (5-1) to (5-20), the formulas (6-1) to (6-7), the formulas (7-1) to (7-28), or the formulas (8-1) to (8-12) when expressed in the structure of R^{y}-Si.

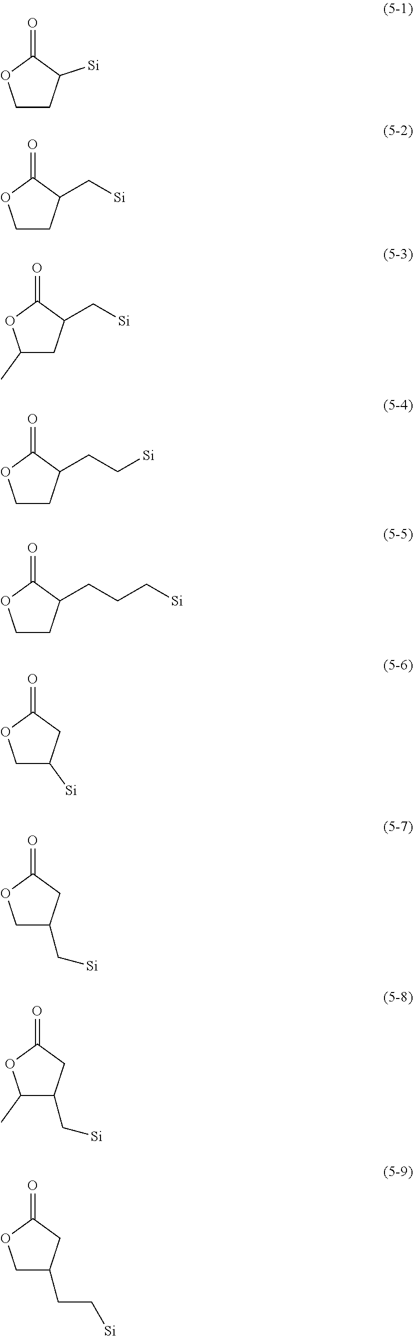

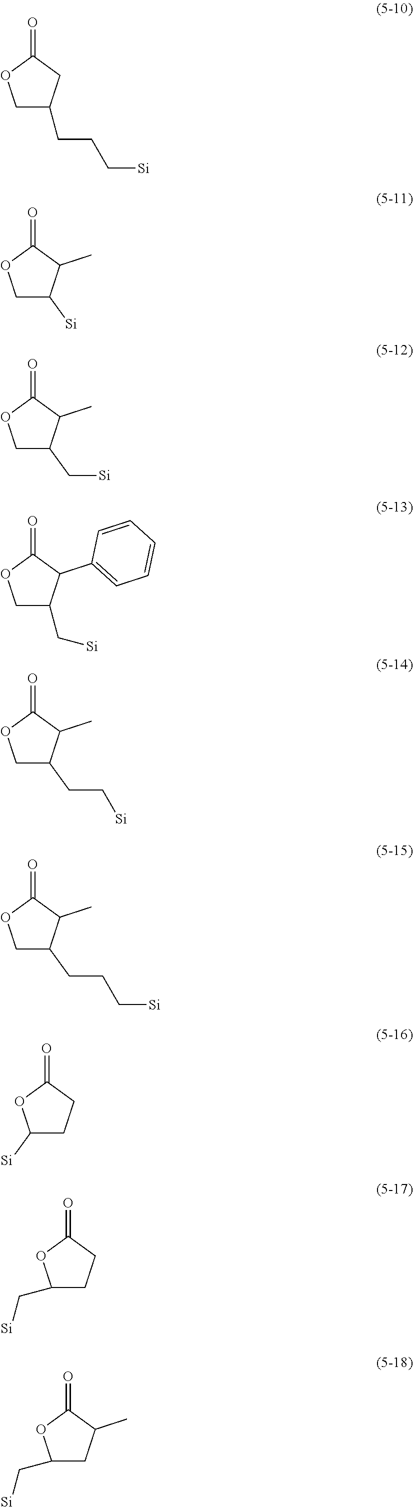

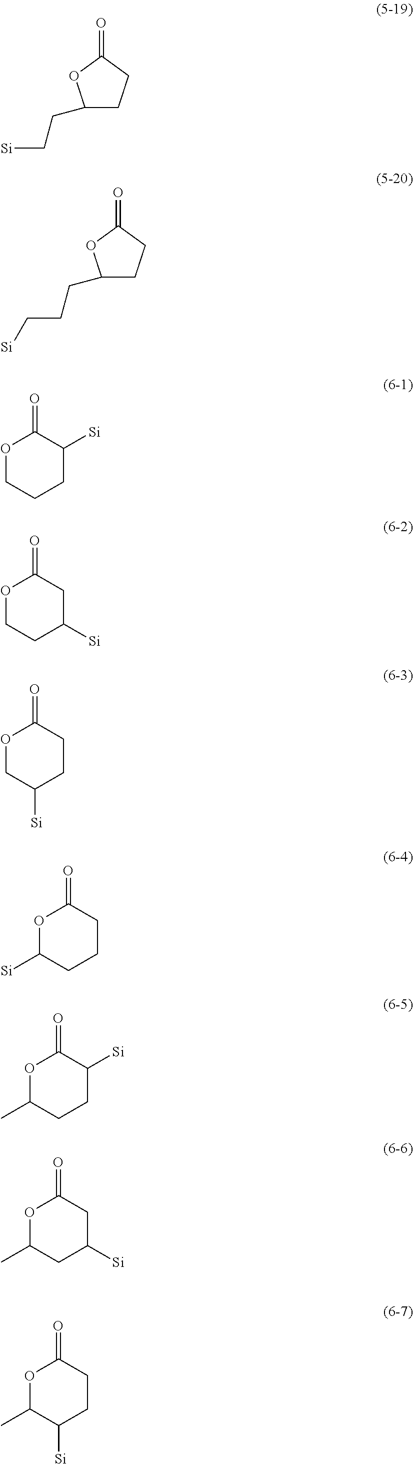

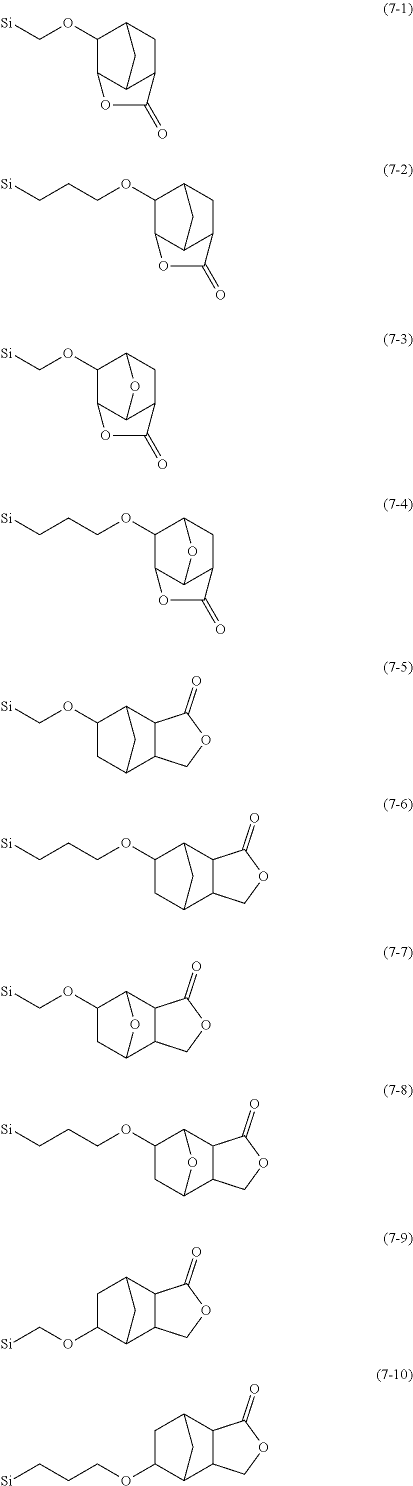

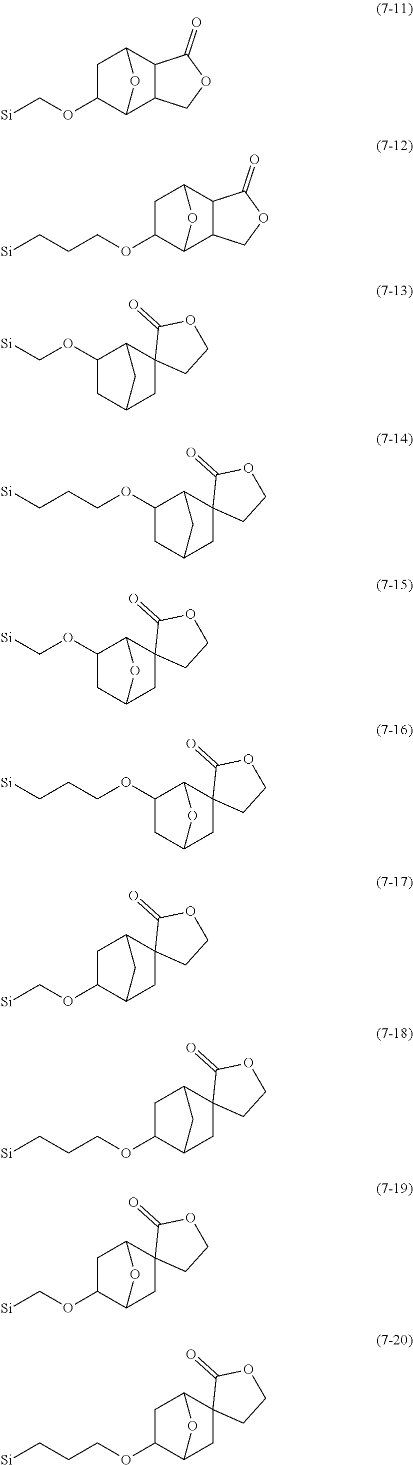

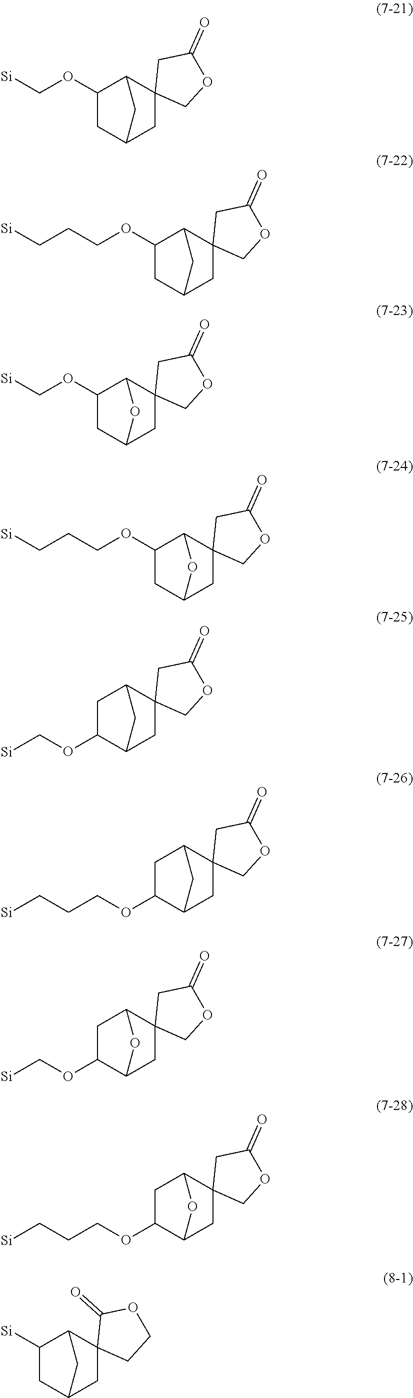

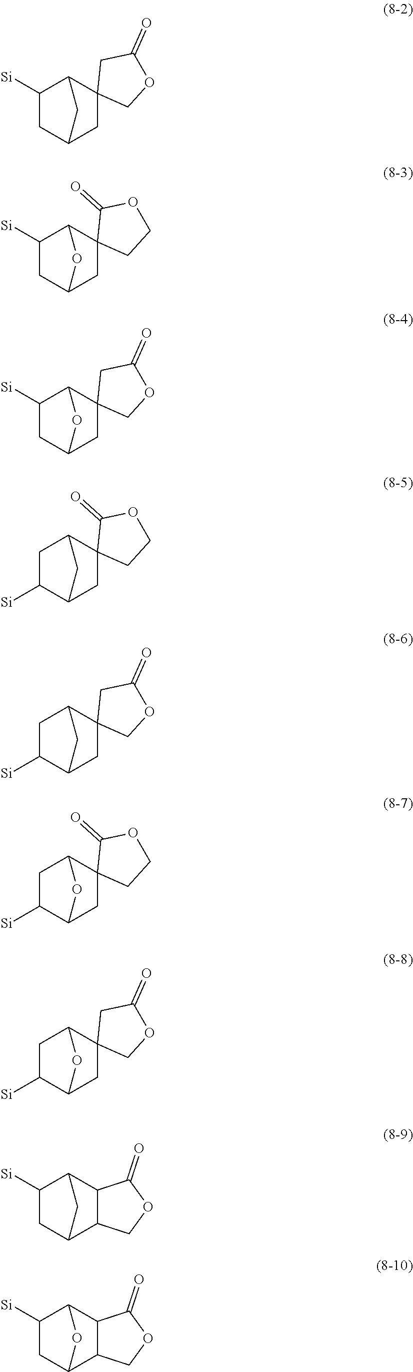

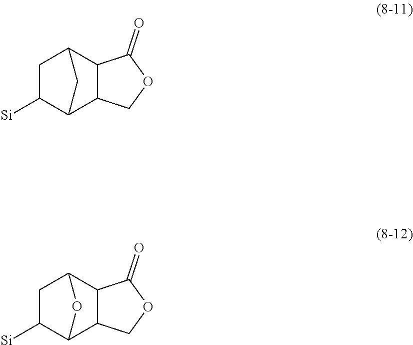

### [Third Structural Unit Represented by the General Formula (3)]

[(R^{W})ₜSiO_{u/2}] (3)

In the general formula (3), R^{W} is a substituent selected from the group consisting of a halogen group, an alkoxy group, and a hydroxy group.

t is a number of 0 or more and less than 4, u is a number of more than 0 and 4 or less and t+u=4.

Further, t is preferably a number of 0 or more and 3 or less. u is preferably a number of 1 or more and 4 or less.

As described above, O_{u/2} in the general formula (3) may have at least one selected from the group consisting of Q1 to Q4 units. It may also include a Q0 unit.

Q0 unit: A structure in which all four bonds of the Si atom are hydrolyzable/polycondensable groups (groups capable of forming a siloxane bonding, such as a halogen group, an alkoxy group, or a hydroxy group).

Q1 unit: A structure in which one of the four bonds of the Si atom forms a siloxane bonding and the remaining three are all hydrolyzable/polycondensable groups.

Q2 unit: A structure in which two of the four Si atom bonds form a siloxane bonding, and the remaining two are all hydrolyzable/polycondensable groups.

Q3 unit: A structure in which three of the four bonds of the Si atom form a siloxane bonding and the remaining one is the hydrolyzable/polycondensable group.

Q4 unit: A structure in which all four bonds of Si atoms form siloxane bondings.

Since the third structural unit represented by the general formula (3) has a structure close to SiO₂ in which organic components are eliminated as much as possible, chemical resistance, heat resistance, transparency and organic solvent resistance can be imparted to the patterned cured film obtained from the negative photosensitive resin composition.

The third structural unit represented by the general formula (3) can be obtained by using tetraalkoxysilane, tetrahalosilane (for example, tetrachlorosilane, tetramethoxysilane, tetraethoxysilane, tetra-n-propoxysilane, tetraisopropoxysilane, etc.), or these oligomers as raw materials, hydrolyzing them, and then polymerizing them (see “Polymerization Method” described later).

As oligomers, examples thereof include silicate compounds such as silicate 40 (average pentameric, manufactured by Tama Chemicals Co., Ltd.), ethyl silicate 40 (average pentameric, manufactured by Colcoat Co., Ltd.), silicate 45 (average heptameric, manufactured by Tama Chemical Industry Co., Ltd.), M silicate 51 (average tetramer, manufactured by Tama Chemicals Co., Ltd.), methyl silicate 51 (average tetramer, manufactured by Colcoat Co., Ltd.), methyl silicate 53A (average heptameric, manufactured by Colcoat Co., Ltd.), ethyl silicate 48 (average decamer, manufactured by Colcoat Co., Ltd.) and EMS-485 (mixture of ethyl silicate and methyl silicate, manufactured by Colcoat Co., Ltd.). From the viewpoint of ease of handling, silicate compounds are preferably used.

When the total Si atom of the polysiloxane compound (A) is 100 mol %, the ratio of the first structural unit in the Si atom is preferably 1 to 100 mol %. Further, it may be more preferably 1 to 80 mol %, further preferably 2 to 60 mol %, and particularly preferably 5 to 50 mol %.

When the second structural unit and the third structural unit are included in addition to the first structural unit, it is preferable that the ratio of each structural unit in Si atoms is in the range of 0 to 80 mol % for the second structural unit and 0 to 90 mol % for the third structural unit, respectively (however, the second structural unit and the third structural unit are 1 to 90 mol % in total). The second structural unit may be more preferably 2 to 70 mol %, still more preferably 5 to 40 mol %. Further, the third structural unit may be more preferably in the range of 5 to 70 mol %, still more preferably in the range of 5 to 40 mol %. Further, the total of the second structural unit and the third structural unit may be more preferably in the range of 2 to 70 mol %, still more preferably in the range of 5 to 60 mol %.

Further, the Si atoms of the first structural unit, the second structural unit and the third structural unit may be contained in a total amount of 1 to 100 mol %. It may be preferably 2 to 80 mol %, more preferably 5 to 60 mol %.

The molar % of Si atoms can be determined, for example, from the peak area ratio in a ²⁹Si-NMR measurement.

### [Other Structural Units (Optional Components)]

In (A) polysiloxane compounds, in addition to the above-mentioned structural units, for the purpose of adjusting solubility in (C) solvents, heat resistance and transparency, etc. when made as a patterned cured film, other structural units containing Si atoms (hereinafter, may be referred to as “optional components”) may be contained. Examples of the optional component include chlorosilane and alkoxysilane. Chlorosilane and alkoxysilane may be referred to as “other Si monomers”.

Specific examples of chlorosilane include dimethyldichlorosilane, diethyldichlorosilane, dipropyldichlorosilane, diphenyldichlorosilane, bis (3,3,3-trifluoropropyl) dichlorosilane, methyl (3,3,3-trifluoropropyl) dichlorosilane, methyltrichlorosilane, ethyltrichlorosilane, propyltrichlorosilane, isopropyltrichlorosilane, phenyltrichlorosilane, methylphenyltrichlorosilane, trifluoromethyltrichlorosilane, pentafluoroethyltrichlorosilane, 3,3,3-trifluoropropyltrichlorosilane and the like.

Specific examples of the alkoxysilane include dimethyldimethoxysilane, dimethyldiethoxysilane, dimethyldipropoxysilane, dimethyldiphenoxysilane, diethyldimethoxysilane, diethyldiethoxysilane, diethyldipropoxysilane, diethyldiphenoxysilane, dipropyldimethoxysilane, dipropyldiethoxysilane, diphenyldimethoxysilane, diphenyldiethoxysilane, diphenyldiphenoxysilane, bis (3,3,3-trifluoropropyl) dimethoxysilane, methyl (3,3,3-trifluoropropyl) dimethoxysilane, methyltrimethoxysilane, ethyltrimethoxysilane, propyltrimethoxysilane, isopropyltrimethoxysilane, phenyltrimethoxysilane, methyltriethoxysilane, methylphenyldiethoxysilane, ethyltriethoxysilane, propyltriethoxysilane, isopropyltriethoxysilane, phenyltriethoxysilane, methyltripropoxysilane, ethyltripropoxysilane, propyltripropoxysilane, isopropyltripropoxysilane, phenyltripropoxysilane, methyltriisopropoxysilane, ethyltriisopropoxysilane, propyltriisopropoxysilane, isopropyltriisopropoxysilane, phenyltriisopropoxysilane, trifluoromethyltrimethoxysilane, pentafluoroethyltrimethoxysilane, 3,3,3-trifluoropropyltrimethoxysilane, 3,3,3-trifluoropropyltriethoxysilane.

The above optional components may be used alone or in combination of two or more.

Of these, phenyltrimethoxysilane, phenyltriethoxysilane, methylphenyldimethoxysilane, and methylphenyldiethoxysilane are preferable for the purpose of enhancing the heat resistance and transparency of the obtained patterned cured film, and dimethyldimethoxysilane and dimethyldiethoxysilane are preferable for the purpose of increasing the flexibility of the obtained patterned cured film and preventing cracks and the like.

When the total Si atoms of (A) the polysiloxane compound is 100 mol %, the ratio of Si atoms contained in the optional component is not particularly limited, but may be, for example, 0 to 99 mol %, preferably 0 to 95 mol %, more preferably 10 to 85 mol %.

The molecular weight of (A) the polysiloxane compound may be 500 to 50,000, preferably 800 to 40,000, and more preferably 1,000 to 30,000 in terms of weight average molecular weight. The molecular weight can be set within a desired range by adjusting the amount of the catalyst and the temperature of the polymerization reaction.

### [Polymerization Method]

Next, a polymerization method for obtaining the (A) polysiloxane compound will be described. The desired polysiloxane compound (A) is obtained by the hydrolyzed polycondensation reaction using halosilanes represented by the general formula (9), alkoxysilanes represented by the general formula (10), and other Si monomers for obtaining the first structural unit, the second structural unit, and the third structural unit. Therefore, (A) the polysiloxane compound is also a hydrolyzed polycondensate.

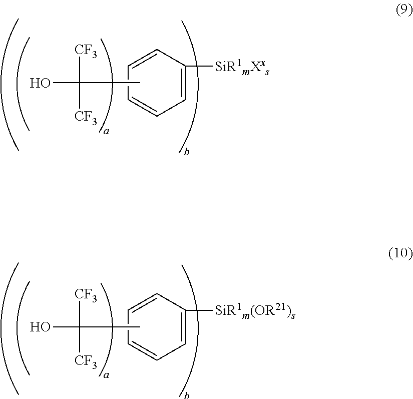

In the general formula (9) and the general formula (10), X^{x} is a halogen atom, R²¹ is an alkyl group, a is an integer of 1 to 5, b is an integer of 1 to 3, m is an integer of 0 to 2, and s is an integer of 1 to 3, b+m+s=4.

The hydrolysis polycondensation reaction can be carried out by a general method in the hydrolysis and condensation reaction of halosilanes (preferably chlorosilane) and alkoxysilane.

To give a specific example, first, after quantitative sampling halosilanes and alkoxysilanes are placed in a reaction vessel at room temperature (particularly, the ambient temperature without heating or cooling, usually about 15° C. or higher and about 30° C. or lower. The same applies hereinafter), water for hydrolyzing halosilanes and alkoxysilanes, a catalyst for advancing the polycondensation reaction, and a reaction solvent, if desired, are added to the reaction vessel to prepare a reaction solution. The order of adding the reaction materials at this time is not limited to this, and the reaction materials can be added in any order to prepare the reaction solution. When other Si monomers are used in combination, they may be added to the reaction vessel in the same manner as the halosilanes and alkoxysilanes.

Next, (A) the polysiloxane compound can be obtained by advancing the hydrolysis and condensation reaction at a predetermined temperature for a predetermined time while stirring the reaction solution. The time required for hydrolysis condensation depends on the type of catalyst, but is usually 3 hours or more and 24 hours or less, and the reaction temperature is room temperature (for example, 25° C.) or more and 200° C. or less. When heating, it is preferable to set the reaction vessel to a closed system or attach a reflux device such as a condenser to reflux the reaction system to prevent unreacted raw materials, water, reaction solvent and/or catalyst in the reaction system from being distilled out of the reaction system. After the reaction, from the viewpoint of handling the (A) polysiloxane compound, it is preferable to remove the water remaining in the reaction system, the alcohol produced, and the catalyst. Water, alcohol, and the catalyst may be removed by an extraction operation, or a solvent such as toluene that does not adversely affect the reaction may be added to the reaction system and azeotropically removed with a Dean-Stark tube.

The amount of water used in the hydrolysis and condensation reactions is not particularly limited. From the viewpoint of reaction efficiency, the amount of water is preferably 0.5 times or more and 5 times or less with respect to the total number of moles of hydrolyzable groups (alkoxy groups and halogen atomic groups) contained in alkoxysilane and halosilanes as the raw materials.

The catalyst for advancing the polycondensation reaction is not particularly limited, but an acid catalyst and a base catalyst are preferably used. Specific examples of acid catalysts include hydrochloric acid, nitric acid, sulfuric acid, hydrofluoric acid, phosphoric acid, acetic acid, oxalic acid, trifluoroacetic acid, methanesulfonic acid, trifluoromethanesulfonic acid, camphorsulfonic acid, benzenesulfonic acid, tosic acid, formic acid, maleic acid, malonic acid, and polyvalent carboxylic acids such as succinic acid, or anhydrides thereof. Specific examples of the base catalyst include triethylamine, tripropylamine, tributylam ine, tripentylam ine, trihexylam ine, triheptylam ine, trioctylam ine, diethylamine, triethanolamine, diethanolamine, sodium hydroxide, potassium hydroxide, sodium carbonate and tetramethylammonium hydroxide. The amount of the catalyst used is preferably 1.0×10⁻⁵ times or more and 1.0×10⁻¹ times or less with respect to the total number of moles of hydrolyzable groups (alkoxy groups and halogen atomic groups) contained in the alkoxysilanes and halosilanes as the raw materials.

In the hydrolysis and condensation reactions, it is not always necessary to use a reaction solvent, and the raw material compound, water and a catalyst can be mixed and hydrolyzed and condensed. On the other hand, when a reaction solvent is used, the type thereof is not particularly limited. Among them, a polar solvent is preferable, and an alcohol solvent is more preferable, from the viewpoint of solubility in a raw material compound, water, and a catalyst. Specific examples thereof include methanol, ethanol, 1-propanol, 2-propanol, 1-butanol, 2-butanol, diacetone alcohol, propylene glycol monomethyl ether and the like. As the amount to be used when the reaction solvent is used, an arbitrary amount necessary for the hydrolysis condensation reaction to proceed in a uniform system can be used. Further, (C) the solvent described later may be used as the reaction solvent.

### [(B) Photoinduced Curing Accelerator]

The negative photosensitive resin composition can be made into a photosensitive resin composition by containing (B) a photoinduced curing accelerator. As (B) the photoinduced curing accelerator, it is preferable to use a photosensitive agent selected from a photoacid generator and/or a photobase generator. Further, when the negative photosensitive resin composition has the photoacid generator and/or the photobase generator, the polycondensation reaction can be promoted by heating after exposure, and the weight average molecular weight can be increased. Further, during the heat treatment of the fourth step described later, a patterned cured film having good chemical resistance can be obtained even at a low temperature of 200° C. or lower.

The photoacid generator and the photobase generator will be described below in this order.

The photoacid generator will be described. The photoacid generator is a compound that generates an acid by irradiation with light, and the acid generated at the exposed site promotes the silanol condensation reaction, that is, the solgel polymerization reaction, and the dissolution rate by the alkaline developer is significantly reduced, that is, resistance to the alkaline developer can be achieved. Further, when (A) the polysiloxane compound has an epoxy group or an oxetane group, it is preferable because each of them can accelerate the curing reaction. On the other hand, the unexposed portion does not cause this action and is dissolved by the alkaline developer, and a pattern corresponding to the shape of the exposed portion is formed.

Specific examples of the photoacid generator include a sulfonium salt, an iodonium salt, a sulfonyldiazomethane, an N-sulfonyloxyimide or an oxime-O-sulfonate. These photoacid generators may be used alone or in combination of two or more. Specific examples of commercially available products include product names: Irgacure 290, Irgacure PAG121, Irgacure PAG103, Irgacure CGI1380, Irgacure CGI725 (all manufactured by BASF in the United States), and product names: PAI-101, PAI-106, NAI-105. NAI-106, TAZ-110, TAZ-204 (all manufactured by Midori Kagaku Co., Ltd.), product names: CPI-200K, CPI-2105, CPI-101A, CPI-110A, CPI-100P, CPI-110P, CPI-310B , CPI-100TF, CPI-110TF, HS-1, HS-1A, HS-1P, HS-1N, HS-1TF, HS-1NF, HS-1MS, HS-1CS, LW-S1, LW-S1NF (all manufactured by San-Apro Ltd.), product name: TFE-triazine, TME-triazine or MP-triazine (all manufactured by SANWA Chemical Co., Ltd.), but the present invention is not limited thereto.

The amount of the photoacid generator as (B) the photo-induced curing accelerator in the negative photosensitive resin composition is not necessarily limited, but when (A) the polysiloxane compound is 100 parts by mass for example, 0.01 part by mass or more and 10 parts by mass or less is preferable, and 0.05 part by mass or more and 5 parts by mass or less is more preferable. By using an appropriate amount of the photoacid generator, it is easy to achieve both sufficient patterning performance and storage stability of the composition.

Next, the photobase generator will be described. A photobase generator is a compound that generates a base (anion) by irradiation with light, and the base generated at the exposed site promotes the sol-gel reaction, and the dissolution rate by the alkaline developer is significantly reduced, that is, resistance to the alkaline developer can be achieved. On the other hand, the unexposed portion does not cause this action and is dissolved by the alkaline developer, and a pattern corresponding to the shape of the exposed portion is formed.

Specific examples of the photobase generator include amides and amine salts. Specific examples of commercially available products include product names: WPBG-165, WPBG-018, WPBG-140, WPBG-027, WPBG-266, WPBG-300, WPBG-345 (all manufactured by FUJIFILM Wako Pure Chemical Corporation)., product names: 2-(9-Oxanthen-2-yl) propionic Acid 1,5,7-Triazabiciclo [4.4.0] dec-5-ene Salt, 2-(9-Oxanthen-2-yl) propionic Acid, Acetophenone O-Benzoyloxime, 2-N itrobenzyl Cyclohexylcarbamate, 1,2-Bis (4-methoxyphenyl)-2-oxoethyl Cyclohexylcarbamate (all manufactured by Tokyo Chemical Industry Co., Ltd.), product name: EIPBG, EITMG, EINAP, NMBC (all manufactured by EIWEISS Chemical Corporation), but not limited to these.

These photoacid generators and photobase generators may be used alone or in combination of two or more, or in combination with other compounds.

Specific examples of the combination with other compounds include combinations with amines such as 4,4′-bis (dimethylamino) benzophenone, 4,4′-bis (diethylamino) benzophenone, diethanolmethylamine, dimethylethanolamine, triethanolamine, ethyl-4-dimethylaminobenzoate and 2-ethylhexyl-4-dimethylaminobenzoate, further combined with iodonium salts such as diphenyliodonium chloride, and dyes such as methylene blue and amines, etc.

The amount of the photobase generator as (B) the photoinduced curing accelerator in the negative photosensitive resin composition is not necessarily limited, but with respect to 100 parts by mass of the polysiloxane compound as (A) the component, for example, 0.01 parts by mass or more and 10 parts by mass or less is preferable, and 0.05 parts by mass or more and 5 parts by mass or less is a more preferable embodiment. By using the photobase generator in the amount shown here, the balance between the chemical resistance of the obtained patterned cured film and the storage stability of the composition can be further improved.

### [(C) Solvent]

(C) The solvent is not particularly limited as long as it can dissolve (A) a polysiloxane compound and (B) a photoinduced curing accelerator. Specifically, examples thereof include propylene glycol monomethyl ether acetate, propylene glycol monomethyl ether, cyclohexanone, ethyl lactate, y-butyrolactone, diacetone alcohol, diglyme, methyl isobutyl ketone, 3-methoxybutyl acetate, 2-heptanone, N,N -dimethylformamide, N,N -dimethylacetamide, N-methylpyrrolidone, glycols and glycol ethers, and glycol ether esters, but are not limited to.

Specific examples of glycol, glycol ether, and glycol ether ester include CELTOR (registered trademark) manufactured by Daicel Corporation and HIGHSOLV (registered trademark) manufactured by TOHO Chemical Industry Co., Ltd. Specifically, cyclohexanol acetate, dipropylene glycol dimethyl ether, propylene glycol diacetate, dipropylene glycol methyl-n-propyl ether, dipropylene glycol methyl ether acetate, 1,4-butanediol diacetate, 1,3-butylene glycol diacetate, 1,6-hexanediol diacetate, 3-methoxybutyl acetate, ethylene glycol monobutyl ether acetate, diethylene glycol monoethyl ether acetate, diethylene glycol monobutyl ether acetate, triacetin, 1,3-butylene glycol, propylene glycol-n-propyl ether , propylene glycol-n-butyl ether, dipropylene glycol methyl ether, dipropylene glycol ethyl ether, dipropylene glycol-n-propyl ether, dipropylene glycol-n-butyl ether, tripropylene glycol methyl ether, tripropylene glycol-n-butyl ether, triethylene glycol dimethyl ether, diethylene glycol butyl methyl ether, and tripropylene glycol dimethyl ether, but are not limited thereto.

The amount of the solvent (C) contained in the negative photosensitive resin composition is preferably 40% by mass or more and 95% by mass or less, and more preferably 50% by mass or more and 90% by mass or less. By setting the solvent content within the above range, it becomes easy to apply and form a uniform resin film with an appropriate film thickness. Further, as (C) the solvent, two or more of the above solvents may be used in combination.

### [Additives (Optional Components)]

The negative photosensitive resin composition can contain the following components as additives as long as the excellent properties of the negative photosensitive resin composition are not significantly impaired.

For example, an additive such as a surfactant may be contained for the purpose of improving coatability, leveling property, film forming property, storage stability, defoaming property and the like. Specifically, examples of commercially available surfactants include, product name MEGAFAC manufactured by DIC Corporation, product number F142D, F172, F173 or F183, product name Fluorad manufactured by 3M Japan, product number, FC-135, FC-170C, FC-430 or FC-431, product name Surflon manufactured by AGC Seimi Chemical Co., Ltd., product numbers S-112, S-113, S-131, S-141 or S-145, or, product names, SH-28PA, SH-190, SH-193, SZ-6032 or SF-8428 manufactured by DuPont Toray Specialty Materials K.K.

When these surfactants are added, the blending amount thereof is preferably 0.001 part by mass or more and 10 parts by mass or less with respect to 100 parts by mass of the polysiloxane compound which is (A) the component. MEGAFAC is the product name of fluorine-based additives (surfactant/surface modifier) of DIC Corporation, Fluorad is the product name of fluorine-based surfactant of 3M Japan, Surflon is the product name of fluorine-based surfactant of AGC Seimi Chemical Co., Ltd., and each is registered as a trademark.

As other components, a curing agent can be blended for the purpose of improving the chemical resistance of the obtained pattern curing film. Examples of the curing agent include a melamine curing agent, a urea resin curing agent, a polybasic acid curing agent, an isocyanate curing agent, and an epoxy curing agent. It is considered that the curing agent mainly reacts with “—OH” of each structural unit of the polysiloxane compound which is (A) the component to form a crosslinked structure.

Specifically, examples include isocyanates such as isophorone diisocyanate, hexamethylene diisocyanate, tolylene diisocyanate or diphenylmethane diisocyanate, and isocyanurates thereof, blocked isocyanates thereof or biuretes thereof, amino compounds such as melamine resins such as alkylated melamine, methylol melamine and imino melamine, and urea resins, or epoxy curing agents having two or more epoxy groups obtained by reacting polyvalent phenol such as bisphenol A with epichlorohydrin. Specifically, a curing agent having a structure represented by the formula (8) is more preferable, and specifically, a melamine derivative represented by the formulas (8a) to (8d) or a urea derivative (product name, Sanwa Chemical Co., Ltd.) can be exemplified (in addition, in the formula (8), the broken line means the combiner).

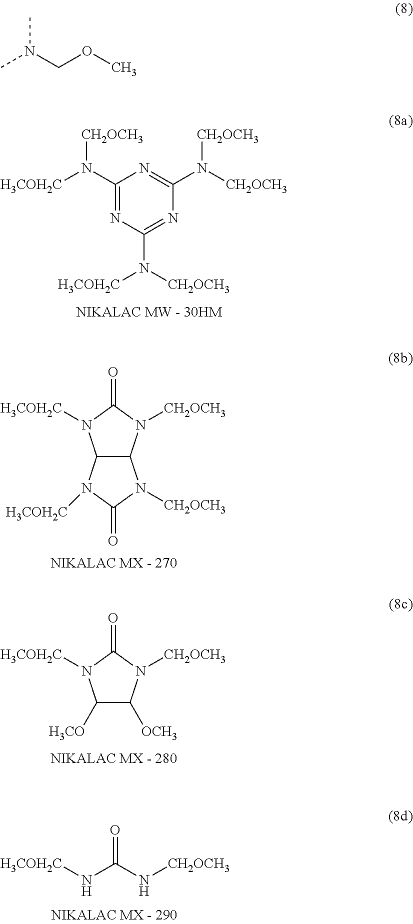

When these curing agents are added, the blending amount thereof is preferably 0.001 part by mass or more and 10 parts by mass or less with respect to 100 parts by mass of (A) the polysiloxane compound.

Moreover, this negative photosensitive resin composition may further contain a sensitizer. By containing the sensitizer, the reaction of (B) the photo-induced curing accelerator is promoted in the exposure treatment, and the sensitivity and the pattern resolution are improved.

The sensitizer is not particularly limited, but a sensitizer that vaporizes by heat treatment or a sensitizer that fades by light irradiation is preferably used. This sensitizer needs to have light absorption for exposure wavelengths (for example, 365 nm (i line), 405 nm (h line), 436 nm (g line)) in the exposure process, but the transparency decreases due to the presence of absorption in the visible light region when the sensitizer remains in the patterned cured film. Therefore, in order to prevent the decrease in transparency due to the sensitizer, the sensitizer used is preferably a compound that vaporizes by heat treatment such as thermosetting, or a compound that fades by light irradiation such as bleaching exposure described later.

Specific examples of the sensitizer that vaporizes by the above heat treatment and the sensitizer that fades by light irradiation include coumarin such as 3,3′-carbonylbis (diethylaminocoumarin), anthraquinone such as 9,10-anthraquinone, and aromatic ketones such as benzophenone, 4,4′-dimethoxybenzophenone, acetophenone, 4-methoxyacetophenone, benzaldehyde, and condensed aromatics such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl) anthracene, 9,10-bis(triphenylsilyl) anthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene, 9,10-bis (trimethylsilylethynyl)anthracene. Commercially available products include ANTHRACURE (manufactured by Kawasaki Kasei Chemicals Ltd.) and the like.

When these sensitizers are added, the blending amount thereof is preferably 0.001 part by mass or more and 10 parts by mass or less with respect to 100 parts by mass of (A) the polysiloxane compound.

In addition, a person skilled in the art may appropriately determine whether to use each of the above sensitizers alone or in combination of two or more, depending on the intended use, usage environment and restrictions.

### [Patterning Method Using Photosensitive Resin Composition]

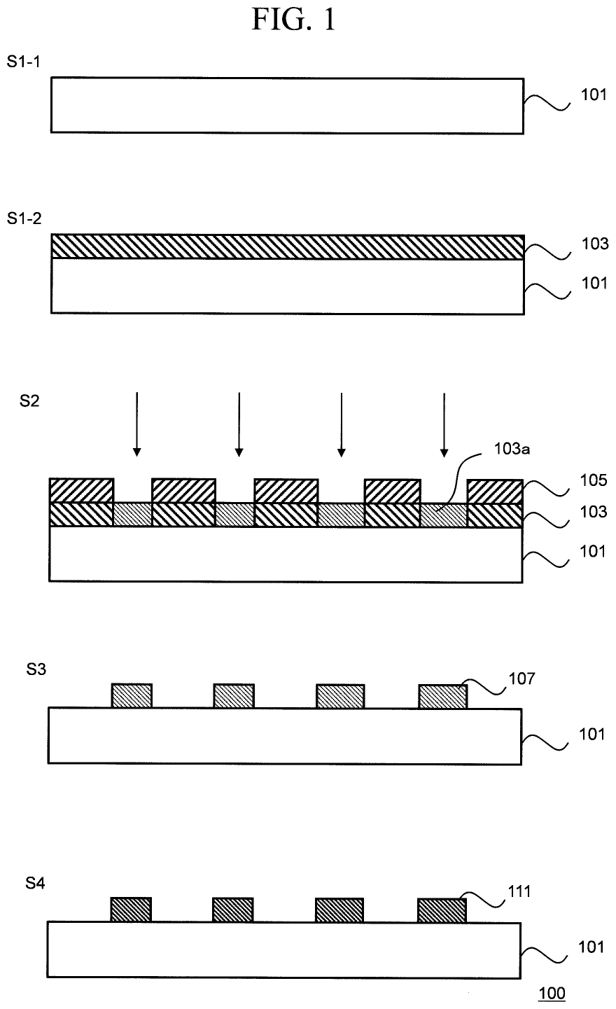

Next, a patterning method using the present negative photosensitive resin composition (also referred to as “method for producing a patterned cured film” in the present specification) will be described. FIG. 1 is a schematic view illustrating a method for manufacturing a patterned cured film 100 according to one embodiment of the present invention.

The “patterned cured film” in the present specification is a cured film obtained by developing a pattern after an exposure step and curing the obtained pattern. This will be described below.

The method for producing the patterned cured film 100 can include the following first to fourth steps.

First step: A step of applying the negative photosensitive resin composition onto a substrate 101 and drying it to form a photosensitive resin film 103.

Second step: A step of exposing the photosensitive resin film 103 via a photomask 105.

Third step: A step of developing the photosensitive resin film 103 after exposure to form a pattern resin film 107.

Fourth step: A step of heating the pattern resin film 107 and thereby curing the pattern resin film 107 to obtain a patterned cured film 111.

### [First Step]

The substrate 101 is prepare (step S1-1 ). The substrate 101 to which the negative photosensitive resin composition is applied is selected from a silicon wafer, and substrates made of a metal, a glass, a ceramic, and a plastic according to the use of the patterned cured film to be formed. Specifically, examples of the substrate used for semiconductors, displays and the like include silicon, silicon nitride, glass, polyimide (Kapton), polyethylene terephthalate, polycarbonate, polyethylene naphthalate and the like. Further, the substrate 101 may have an optional layer of a silicon, a metal, glass, a ceramic, a resin or the like on the surface, and “on the substrate” may be on the surface of the substrate or via the layer.

As a coating method on the substrate 101, a known coating method such as spin coating, dip coating, spray coating, bar coating, applicator, inkjet or roll coater can be used without particular limitation.

Then, the photosensitive resin film 103 can be obtained by drying the substrate 101 coated with the negative photosensitive resin composition (step S1-2). in the drying treatment, the solvent may be removed to the extent that the obtained photosensitive resin film 103 does not easily flow or deform, and it may be heated at, for example, 80 to 120° C. for 30 seconds or more and 5 minutes or less.

### [Second Step]

Next, the photosensitive resin film 103 obtained in the first step is exposed to light by a light-shielding plate (photomask) 105 having a desired shape for forming a desired pattern. Then, the photosensitive resin film 103 after exposure is obtained (step S2). The photosensitive resin film 103 after exposure includes an exposed portion 103a, which is an exposed portion, and an unexposed portion.

A known method can be used for the exposure treatment. As the light source, light rays having a light source wavelength in the range of 1 nm to 600 nm can be used. Specifically, a low-pressure mercury lamp, a high-pressure mercury lamp, an ultra-high-pressure mercury lamp, a KrF excimer laser (wavelength 248 nm), an ArF excimer laser (wavelength 193 nm), or EUV light (wavelength 13.5 nm) and the like can be used. The exposure amount can be adjusted according to the type and amount of the photo-induced curing accelerator used, the manufacturing process, etc., and is not particularly limited, but may be about 1 to 10,000 mJ/cm², preferably 10 to 5,000 mJ/cm².

When the negative photosensitive resin composition is used, the condensation and curing reactions can be further promoted, and the weight average molecular weight can be increased by heating the photosensitive resin film 103 after exposure before the developing step. By increasing the weight average molecular weight, the resistance of the exposed portion to the alkaline solution can be improved, and the contrast between the exposed portion and the unexposed portion can be improved, which is preferable. When heating, only the exposed part may be heated, but it is more convenient to heat the exposed part and the unexposed part. In that case, if a heating temperature after the exposure is 60° C. to 180° C. and a heating time after exposure is 30 seconds to 10 minutes, the condensation and curing reaction of the exposed portion is promoted to improve the resistance to the alkaline solution. It is preferable because it is possible to suppress the condensation and curing reaction of the unexposed portion and not impair the solubility in the alkaline solution. The heating temperature after exposure may be more preferably 60° C. to 170° C.

Further, in the case of a negative photosensitive resin composition capable of lowering the heating temperature to 200° C. or lower in the fourth step described later, a heating temperature before the developing step is preferably set to the heating temperature or lower in the fourth step. For example, the heating temperature before the developing step may be preferably the heating temperature of −10° C. or lower in the fourth step.

### [Third Step]

Next, by developing the photosensitive resin film 103 after exposure obtained in the second step, the film other than the exposed portion 103a is removed, and a film having a pattern of a desired shape (hereinafter, sometimes referred to as a “pattern resin film”) 107 can be formed (step S3).

Development is the formation of a pattern by using an alkaline solution as a developer to dissolve, wash and remove the unexposed portion.

The developer to be used is not particularly limited as long as it can remove the photosensitive resin film in the unexposed portion by a predetermined developing method. Specific examples thereof include an inorganic alkali, a primary amine, a secondary amine, a tertiary amine, an alcohol amine, a quaternary ammonium salt, and an alkaline aqueous solution using a mixture thereof.

More specifically, alkaline aqueous solutions such as potassium hydroxide, sodium hydroxide, ammonia, ethylamine, diethylamine, triethylamine, triethanolamine, and tetramethylammonium hydroxide (abbreviation: TMAH) can be exemplified. Above all, it is preferable to use a TMAH aqueous solution, and in particular, it is preferable to use a TMAH aqueous solution of 0.1% by mass or more and 5% by mass or less, more preferably 2% by mass or more and 3% by mass or less.

As the developing method, a known method such as a dipping method, a paddle method, or a spraying method can be used, and the developing time may be 0.1 minutes or more and 3 minutes or less. Further, it is preferably 0.5 minutes or more and 2 minutes or less. After that, washing, rinsing, drying, etc. are performed as necessary to form the desired pattern resin film 107 on the substrate 101.

Further, it is preferable to further perform bleaching exposure after forming the pattern resin film 107. The purpose is to improve the transparency of the finally obtained pattern curing film 111 by photodegrading the photoinduced curing accelerator remaining in the pattern resin film 107. For the bleaching exposure, the same exposure processing as in the second step can be performed.

### [Fourth Step]

Next, the pattern resin film (including the bleaching exposed pattern resin film) 107 obtained in the third step is heat-treated to obtain the final patterned cured film 111 (step S4). By the heat treatment, it becomes possible to condense the alkoxy group and silanol group remaining as unreactive groups in (A) the polysiloxane compound. Further, if the photoinduced curing accelerator remains, it can be removed by thermal decomposition.

The heating temperature at this time is preferably 80° C. or higher and 400° C. or lower, and more preferably 100° C. or higher and 350° C. or lower. The heat treatment time may be 1 minute or more and 90 minutes or less, and preferably 5 minutes or more and 60 minutes or less. Further, as described above, when a negative photosensitive resin composition containing a photoacid generator and/or a photobase generator is used, heat treatment at a low temperature is possible. The heating temperature may be preferably 200° C. or lower, more preferably 180° C. or lower, and even more preferably 160° C. or lower. The lower limit may be, for example, 80° C. or higher, preferably 100° C. or higher. When a negative photosensitive resin composition containing a photoacid generator and/or a photobase generator is used, the condensation, curing reaction, and the heat decomposition of the photoinduced curing accelerator proceeds easily by setting the heating temperature within the above range, and a desired chemical resistance, heat resistance, and transparency can be obtained. In addition, it is possible to suppress thermal decomposition of the polysiloxane compound and cracks in the formed film, and it is possible to obtain a film having good adhesion to the substrate. By this heat treatment, the desired patterned cured film 111 can be formed on the substrate 101.

### [Pattern Structure]

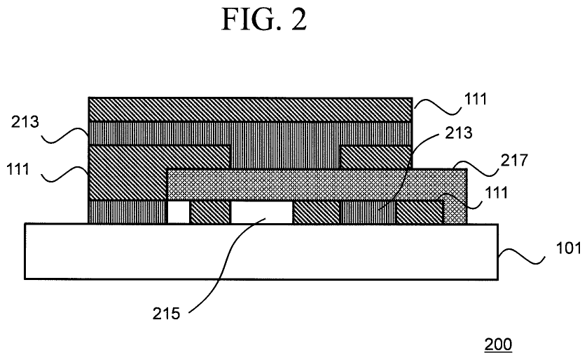

A pattern structure 200 including a patterned cured film (hereinafter, also referred to as a first structure) 111 produced by the above method and a structure other than the patterned cured film (hereinafter, also referred to as a second structure) 213 or a void 215 will be described. FIG. 2 is a schematic view of the pattern structure 200 according to one embodiment of the present invention.

The pattern structure 200 includes a first structure 111 containing (A) a polysiloxane compound formed on a substrate 101 and containing a first structural unit represented by the following general formula (1A), and (B) a modified product of a photoinduced curing accelerator, and a second structure 213 containing a component different from the first structure and/or a void 215.

[(R^{x1})_{b1}R¹¹ₘ₁SiO_{n1/2}] (1A)

In the general formula (1A), R^{x1} is a monovalent group represented by the following general formula (1Aa).

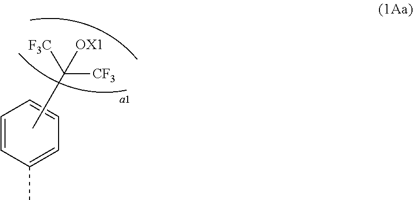

R¹¹ is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms.

b1 is a number of 1 or more and 3 or less, ml is a number of 0 or more and less than 3, n1 is a number of more than 0 and 3 or less, and b1+m1+n1=4.

When there are a plurality of R^{x1} and R¹¹, R^{x1} and R¹¹ are independently selected from any of the substituents described above.

In the general formula (1Aa), X1 is a hydrogen atom or a binding site with Si or C contained in a structural unit different from the first structural unit represented by the general formula (1A), and al is 1 or more and 5 or less, and the broken line represents the bound.

Here, in the first structural unit represented by the general formula (1A), b1, m1 and n1 are theoretical values of bl being an integer of 1 to 3, ml being an integer of 0 to 3, and n1 being an integer of 0 to 3. Further, b1+m1+n1=4 means that the total of the theoretical values is 4. However, for example, since b1, m1 and n1 are obtained as average values in the values obtained by a ²⁹Si NMR measurement, b1 of the average value may be a decimal number rounded to 1 or more and 3 or less, and m1 may be a decimal number rounded to 0 or more and 3 or less (however, m1<3.0) and n1 may be a decimal number rounded to 0 or more and 3 or less (however n1≠0).

Further, b1 is preferably a number of 1 or more and 2 or less. m1 is preferably a number of 0 or more and 2 or less, and more preferably 0 or more and 1 or less. n1 is preferably a number of 1 or more and 3 or less, and more preferably 2 or more and 3 or less.

(A) the polysiloxane compound contained in the first structure 111 preferably includes a second structural unit represented by the following general formula (2A) and/or a third structural unit represented by the following general formula (3A).

[(R^{y1})_{c1}R²¹ₚ₁SiO_{q1/2}] (2A)

[(R^{W1})ₜ₁SiO_{u1/2}] (3A)

In the general formula (2A), R^{y1} is a group by ring-opening or polymerizing a substituent selected from a monovalent organic group having 1 to 30 carbon atoms, including any of an epoxy group, an oxetane group, an acryloyl group, a methacryloyl group or a lactone group. Further, the number of carbon atoms including unreacted substituents (that is, substituents selected from monovalent organic groups having 1 or more and 30 or less carbon atoms containing any of epoxy group, oxetane group, acryloyl group, methacryloyl group or lactone group) may be included as long as the transparency of the obtained patterned cured film is not significantly impaired.

R²¹ is a substituent selected from the group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms.

C1 is a number of 1 or more and 3 or less, p1 is a number of 0 or more and less than 3, q1 is a number of more than 0 and 3 or less, and c1+p1+q1=4.

When there are a plurality of R^{y1} and R²¹, R^{y1} and R²¹ are each independently selected from the substituents described above.

Here, in the second structural unit represented by the general formula (2A), c1, p1 and q1 are theoretical values of c1 being an integer of 1 to 3, p1 being an integer of 0 to 3, and q1 being an integer of 0 to 3. Further, c1+p1+q1=4 means that the total of the theoretical values is 4. However, for example, since c1, p1 and q1 are obtained as average values in the values obtained by a ²⁹Si NMR measurement, c1 of the average value may be a decimal number rounded to 1 or more and 3 or less, and p1 may be a decimal number rounded to 0or more and 3 or less (however, p1<3.0) and q1 may be a decimal number rounded to 0 or more and 3 or less (however, q1≠0).

Further, c1 is preferably a number of 1 or more and 2 or less, and more preferably 1. p1 is preferably a number of 0 or more and 2 or less, and more preferably 0 or more and 1 or less. q1 is preferably a number of 1 or more and 3 or less, and more preferably 2 or more and 3 or less.

In the general formula (3A), R^{W1} is a substituent selected from the group consisting of a halogen group, an alkoxy group, and a hydroxy group.

t1 is a number of 0 or more and less than 4, u1 is a number more than 0 and of 4 or less, and t1+u1=4.

Further, in the third structural unit represented by the general formula (3A), t1 and u1 are theoretical values of t1 being an integer of 0 to 4 and u1 being an integer of 0 to 4. Further, t1+u1=4 means that the total theoretical value is 4. However, for example, since t1 and u1 are obtained as average values in the values obtained by a ²⁹Si NMR measurement, t1 of the average value may be a decimal number rounded to 0 or more and 4 or less (however, t1<4.0), u1 may be a decimal number rounded to 0 or more and 4 or less (however, u1≠0).

Further, t1 is preferably a number of 0 or more and 3 or less. u1 is preferably a number of 1 or more and 4 or less.

For other constitutions of the first structure 111, refer to the description of the constitutions of the negative photosensitive resin composition described above.

Note that R^{x1}, R¹¹, X1, R^{y1}, and R²¹ refer to the above-mentioned constitutions of R^{x}, R¹, X, R^{y}, and R², but the first structure 111 is different from the negative photosensitive resin composition, since the film is cured by light exposing the negative photosensitive resin composition.

When the change in the film thickness of the first structure 111 after being immersed in a chemical solution (organic solvent, acidic solution, basic solution) was evaluated in Examples described later, it was found that the amount of change was small with respect to any of the chemical solutions. This indicates that dissolution in the chemical solution and swelling by the chemical solution can be suppressed, and because it is easy to suppress deformation of the pattern and dimensional change and occurrence of problems such as cracks, defects, etc. when the above-mentioned second structure 213 and/or void 215 is laminated, it is preferable as the first structure 111 constituting the pattern structure 200.

That is, the first structure 111 may preferably satisfy at least one selected from the group consisting of the following (a), (b), and (c). Further, more preferably, all of (a), (b), and (c) may be satisfied.

(a) When the patterned cured film is immersed in an organic solvent at 40° C. for 7 minutes, the rate of change of the film thickness after immersion with respect to the original film thickness is ±5% or less.

(b) When the patterned cured film is immersed in an acidic solution at room temperature environment for 1 minute, the rate of change of the film thickness after immersion with respect to the original film thickness is ±5% or less.

(c) When the patterned cured film is immersed in a basic solution at room temperature environment for 1 minute, the rate of change of the film thickness after immersion with respect to the original film thickness is ±5% or less.

The above-described “organic solvent” is not particularly limited as long as it is a general solvent used for film formation, but for example, N-methyl-2-pyrrolidone (NMP), PGMEA, PGME, MEK, acetone, cyclohexanone, γ-butyrolactone and the like can be exemplified.

The above-described “acidic solution” is not particularly limited, and examples thereof include chemical solutions used for etching metal members obtained by spatter film formation and the like, and specific examples thereof include sulfuric acid, nitric acid, hydrochloric acid, phosphoric acid, acetic acid, hydrobromic acid, and aqueous solutions thereof, and the like.

The above-mentioned “basic solution” is not particularly limited, and examples thereof include general chemicals for removing a resist, and specific examples thereof include organic amine compounds such as monoethanolamine, N-methylaminoethanol, and isopropanolamine, glycol ether compounds such as ethylene glycol monobutyl ether, diethylene glycol monobutyl ether, and triethylene glycol monobutyl ether, dimethylsulfoxide, isopropanol, and aqueous solutions thereof.

Further, when the adhesion of the patterned cured film to the substrate was evaluated in the examples described later, it was found that the patterned cured film had good adhesion. In particular, the first structure 111 is a negative-type patterned cured film as described above, and the negative-type patterned cured film may be used as a permanent film. Therefore, it is preferable that the first structure 111 has high adhesion to the substrate.

That is, the first structure 111 may be preferable in that after the cross-cut test performed by a method conforming to JIS K 5600-5-6 (cross-cut method), visible peeling at a portion to which the test is applied is observed. More preferably, the first structure 111 may satisfy the following (d) and/or (e).

(d) In a method conforming to JIS K 5600-5-6 (cross-cut method), 25 squares having a size of 1 mm square are formed on the patterned cured film formed on the substrate with a cutter knife, and after holding in an environment at 85° C., and 85% relative humidity for 7 days, cellophane tape is attached to the grid and it is visually observed when it is peeled off. As a result, the cut lines are completely smooth and there is no peeling in the square of any grid (classification 0).

(e) In a method conforming to JIS K 5600-5-6 (cross-cut method), 25 squares having a size of 1 mm square are formed on the patterned cured film formed on the substrate with a cutter knife, and after holding in an environment at 121° C., 100% relative humidity and 2 atm for 1 day, cellophane tape is attached to the grid and it is visually observed when it is peeled off. As a result, the cut lines are completely smooth and there is no peeling in the square of any grid (classification 0).

Further, the first structure 111 may preferably satisfy at least one selected from the group consisting of the above (a) to (e), and more preferably satisfy all of (a) to (e).

Further, the weight average molecular weight of (A1) the polysiloxane compound of the first structure 111 may be 750 to 500,000.

The second structure 213 shown in FIG. 2 can contain a component different from that of the first structure. Examples of the second structure 213 include electrodes such as copper, aluminum, and solder, and optical waveguides in which various fillers such as silica and titanium oxide are contained to adjust the refractive index.

Further, for example, when the pattern structure is an element such as MEMS, the void 215 can be exemplified.

The first structure 111 and the second structure 213 may be in direct contact with each other, or may be arranged via an optional layer 217, a gap 215, or the like. Further, the arrangement on the substrate 101 may be appropriately determined according to the application, and is not particularly limited. Specifically, the second structure 213 may be arranged between the substrate 101 and the first structure 111, the first structure 111 may be arranged between the substrate 101 and the second structure 213, the first structure 111 and the second structure 213 may be arranged side by side when viewed from the substrate 101, or a plurality of the first structure 111 and the second structure 213 may be laminated.

### Another Embodiment: A Negative Photosensitive Resin Composition Containing (A1) Component, (A2) Component, (B) Photoinduced Curing Accelerator, and (C) Solvent

“Another embodiment” of the present invention is a resin composition containing the following (A1) component, (A2) component, (B) a photoinduced curing accelerator, and (C) a solvent.

(A1) component: A polymer containing the structural unit represented by the general formula (1), but not containing either the structural unit of the general formula (2) or the structural unit of the general formula (3).

(A2) component: A polymer containing at least one of the structural unit represented by the general formula (2) and the structural unit represented by the general formula (3), but not containing the structural unit represented by the formula (1).

(B) Photoinduced curing accelerator

(C) Solvent

“Structural unit represented by the general formula (1) (hereinafter, may be referred to as ‘structural unit of the general formula (1)’)”, “Structural unit represented by the general formula (2) (hereinafter, ‘The structural unit of the general formula (2)’)” and “Structural unit represented by the general formula (3) (hereinafter, may be described as the ‘structural unit of the general formula (3)’)” can be described again by the same definition as previously defined in the specification (the same favorable substituents described above can also be given as examples).

The difference in the negative photosensitive resin composition of the present embodiment is that the structural unit of the general formula (1) is a polymer called (A1) the component, and the structural unit of the general formula (2) or the general formula (3) is a different polymer called (A2). Of these, the polymer of (A1) the component is a known substance according to Japanese laid-open patent publication No. 2015-129908, and can be synthesized according to the polymerization method described in Japanese laid-open patent publication No. 2015-129908 or the above-described polymerization method. On the other hand, the polymer of (A2) the component can also be synthesized according to a known method by hydrolysis polycondensation or the above-described polymerization method.

As “(B) the photoinduced curing accelerator” and its amount, those listed in the above-described embodiment can be described again.

As “(C) the solvent” and its amount, those listed in the above-described embodiment can be described again.

Unlike the negative photosensitive resin composition described above, the negative photosensitive resin composition having such a structure is a blend (mixture) of different kinds of polymers in the state of the “negative photosensitive resin composition”. However, when the “negative photosensitive resin composition containing (A1) component, (A2) component, (B) photo-induced curing accelerator, and (C) solvent” is applied onto the substrate, exposed and developed after drying and a heat treatment (curing step) is performed, a reaction between silanol groups of different molecules (formation of a siloxane bonding) and a curing reaction of an epoxy group, an oxetane group, an acryloyl group, and a methacryloyl group occur to form a patterned cured film. In this case, the final patterned cured film is “a resin containing a structural unit represented by the general formula (1A), and at least one of the structural units of a structural unit represented by the general formula (2A) and a structural unit represented by the general formula (3A).”.

Even such a polymer (polysiloxane compound) has excellent physical properties similar to the negative photosensitive resin composition of the above-described embodiment, and therefore, the same merit can also be obtained in this embodiment.

On the other hand, “negative photosensitive resin composition containing (A1) component, (A2) component, (B) photoinduced curing accelerator, and (C) solvent” compared with the above-described “negative photosensitive resin composition containing (A) component, (B) a photoinduced curing accelerator and (C) a solvent” has a merit that adjustment for obtaining a desired performance is easy. Specifically, by simply adjusting the blending ratio of (A1) the component and (A2) the component according to the desired performance, it is not necessary to carry out new polymerization or the like, and the film physical properties, alkali developability, and other physical properties can be easily adjusted.

For the meaning of each substituent and the number of substituents in the structural units of the general formulas (1) to (3) in (A1) the component and (A2) the component, the description of the structural units of the general formula (1) to the general formula (3) for (A) the component can be described again. Regarding the preferable amount ratio of (A1) the component and (A2) the component, (from the viewpoint that these are incorporated into one molecule after the final curing), the above-described “Amount ratio between structural units” in “negative photosensitive resin composition containing (A) component, (B) component, (B) photo-induced curing accelerator and (C) solvent” can be described again by changing to “Amount ratio of (A1) component and (A2) component”.

Further, regarding the description of the type and amount of (B) the photo-induced curing accelerator, the above-described “negative photosensitive resin composition including (A) component, (B) photo-induced curing accelerator, and (C) solvent ” can be described again. Regarding the patterning method using the photo-induced curing accelerator, the above-described methods and conditions can be described again.

The type and amount of (C) the solvent which are also described in the above-described “negative photosensitive resin composition containing (A) component, (B) photoinduced curing accelerator, and (C) solvent” can be described again.

The above-described “optional component” is also not prevented from being used in this embodiment.

In addition, the above-mentioned “negative photosensitive resin composition containing (A) component, (B) photoinduced curing accelerator, (C) solvent”, and “negative photosensitive resin composition containing (A1) component, (A2) component, (B) photoinduced curing accelerator and (C) solvent ” can be used in combination. The mixing ratio of the two is arbitrary, and may be appropriately set by those skilled in the art according to the intended use, usage environment and restrictions.

The molecular weight of the polysiloxane compound as (A1) the component may be a weight average molecular weight of 700 to 100,000, preferably 800 to 10000, and more preferably 1,000 to 6,000. The molecular weight can be basically controlled by adjusting the amount of the catalyst and the temperature of the polymerization reaction.

The range of the molecular weight of the polysiloxane compound as (A2) the component is preferably the same range as the molecular weight of (A1) the component.

### [Method for Synthesizing the Raw Material Compound of the Structural Unit of the General Formula (1)]

In the negative photosensitive resin composition, polymerization raw materials, alkoxysilanes represented by the formula (10) and halosilanes represented by the formula (9) for giving the structural unit of the formula (1) among the (A) component and (A1) component are known compounds according to Japanese laid-open patent publication No. 2015-129908 and International patent publication No. WO2019/167770, and it may be synthesized according to the explanation of these documents.

### EXAMPLES

Hereinafter, the present invention will be described in more detail with reference to examples, but the present invention is not limited to the following examples as long as the gist of the present invention is not exceeded.

In the examples, unless otherwise specified, some compounds are described as follows.

Ph-Si: Phenyltriethoxysilane

TMAH: Tetramethylammonium hydroxide

KBM-303: Shin-Etsu Chemical Co., Ltd., 2-(3,4-epoxycyclohexyl) ethyltrimethoxysilane

KBM-5103: Shin-Etsu Chemical Co., Ltd., 3-acryloxypropyltrimethoxysilane

PGMEA: propylene glycol monomethyl ether acetate

KBM-503: Shin-Etsu Chemical Co., Ltd., 3-Methyloxypropyltrimethoxysilane

HFA-Si: Compound represented by the following chemical formula

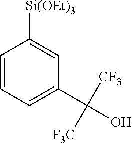

The equipment used for various measurements and the measurement conditions will be described.

### (Nuclear Magnetic Resonance (NMR))

¹H-NMR and ¹⁹F-NMR were measured using a nuclear magnetic resonance apparatus (manufactured by JEOL Ltd., device name: JNM-ECA-400) having a resonance frequency of 400 MHz.

### (Gel Permeation Chromatography (GPC))

Using a high-speed GPC device manufactured by Tosoh Corporation, device name HLC-8320GPC, the weight average molecular weight in terms of polystyrene was measured.

### (Gas Chromatography (GC) Measurement)

The GC measurement was performed using the product name Shimadzu GC-2010 plus manufactured by Shimadzu Corporation, and the column was a capillary column DB5 (30 m×0.25 mmφ×0.25 μm).

### Synthesis of HFA-Si

### Synthesis Example 1

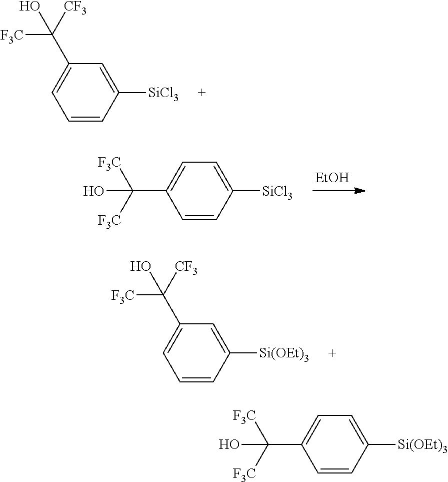

47.70 g (1,035 mmol) of absolute ethanol, 81.00 g (801 mmol) of triethylamine, and 300 g of toluene were added to a 1 L volume 4-necked flask equipped with a thermometer, a mechanical stirrer, and a Dimroth condenser and replaced under a dry nitrogen atmosphere. The contents of the flask were cooled to 0° C. by stirring.

Next, 100.00 g of a mixture of 3-(2-hydroxy-1,1,1,3,3,3-hexafluoroisopropyl)-trichlorosilylbenzene and 4-(2-hydroxy-1,1,1,3,3,3-hexafluoroisopropyl)-trichlorosilylbenzene (GC area ratio 1-3-substitute: 1-4-substitute=96:4) was added dropwise over 1 hour. At that time, the liquid was added dropwise while being cooled in an ice bath so that the liquid temperature was kept below 15° C.

After completion of the dropping, the temperature was raised to 30° C. and the mixture was stirred for 30 minutes to complete the reaction. Subsequently, the reaction solution was suction-filtered to remove salts, and then the organic layer was washed with water using 300 g of pure water three times with a liquid separation funnel, and toluene was distilled off with a rotary evaporator to obtain 92.24 g of a mixture (GC area %: total of 1-3 substitute and 1-4 substitute=91.96% (1-3 substitute=88.26%, 1-4 substitute=3.70) %)) of 3-(2-)hydroxy-1,1,1,3,3,3-hexafluoroisopropyl)-triethoxysilylbenzene and 4-(2-hydroxy-1,1,1,3,3,3-hexafluoroisopropyl)-triethoxysilylbenzene. The yield based on phenyltrichlorosilane was 82%.

Further, by precision distillation of the obtained crude product, 3-(2-hydroxy-1,1,1,3,3,3-hexafluoroisopropyl)-triethoxysilylbenzene (GC area %=97%) was obtained as a colorless transparent liquid. ¹H-NMR and ¹⁹F-NMR measurement results of the obtained 3-(2-hydroxy-1,1,1,3,3,3-hexafluoroisopropyl)-triethoxysilylbenzene (HFA-Si) (chemical shift (δ); ppm) are shown below.

¹H-NMR (solvent CDCl₃, TMS): δ8.00 (s, 1H), 7.79-7.76 (m, 2H), 7.47 (t, J=7.8 Hz, 1H), 3.87 (Q, J=6.9 Hz, 6H), 3.61 (s, 1H), 1.23 (t, J=7.2 Hz, 9H)

¹⁹F-NMR (solvent CDCl₃, CCl₃F): δ-75.99 (S, 6F)

### Synthesis of Polysiloxane Compound

### Synthesis Example 2

### Synthesis of Polysiloxane Compound 1 (HFA-Si/Ph-Si=1/9 Composition (Molar Ratio))

5.0 g (11.9 mmol) of HFA-Si, 25.7 g (107 mmol) of Ph-Si, 6.75 g (375 mmol) of pure water, 0.9 g (3.6 mmol) of acetic acid were added in a reaction vessel, and reacted at 40° C. for 1 hour, 70° C. for 1 hour, and 100° C. for 2 hours. After the reaction, cyclohexanone (60 g) was further added and the reaction was carried out at 130° C. for 2 hours.

After the reaction, the mixture was cooled to about room temperature, 30 g of pure water was added, and washing with water was repeated twice. Cyclohexanone was removed from the obtained organic layer using an evaporator, and 24 g of polysiloxane compound 1 (yield 100%) was obtained. The weight average molecular weight Mw measured by GPC was 1,500.

### Synthesis Example 3

### Synthesis of Polysiloxane Compound 2

6.10 g (15 mmol) of 4-(2-hydroxy-1,1,1,3,3,3-hexafluoroisopropyl)-1-triethoxysilylbenzene, 0.81 g (45 mmol) of pure water and 0.045 g (0.75 mmol) of acetic acid were added, and the mixture was stirred at 100° C. for 12 hours. After completion of the reaction, toluene was added and pure water, ethanol to be produced, and acetic acid were distilled while refluxing (bath temperature 150° C.), and finally toluene was distilled to obtain 4.43 g of polysiloxane compound 2A. As a result of measuring GPC, Mw=7022. As a result of measuring the thermal decomposition temperature, T_{d5} was 388° C.

1.476 g of the above polysiloxane compound 2A, 0.031 g (0.25 mmol) of N,N-dimethyl-4-aminopyridine, 5 mL of pyridine, and 2.183 g (10 mmol) of di-tert-butyl dicarbonate were added in a 20 mL flask, and the reaction was carried out by stirring at 100° C. for 15 hours. After completion of the reaction, pyridine and the remaining di-tert-butyl dicarbonate were distilled to obtain 1.449 g of polysiloxane compound 2. As a result of measuring GPC, Mw=3766. Polysiloxane compound 2: A compound which is the same as the general formula (1) except that R^{x} of the general formula (1) is represented by the following chemical formula, and does not correspond to the general formula (1).

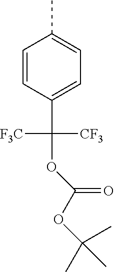

### Synthesis Example 4

### Synthesis of Polysiloxane Compound 3 (HFA-Si/Ph-Si/KBM-303=1/8/1 Composition (Molar Ratio))

10.0 g (23.8 mmol) of HFA-Si, 45.8 g (190 mmol) of Ph-Si, 5.9 g (23.4 mmol) of KBM-303, 13.5 g (750 mmol) of pure water, 1.7 g (28.3 mmol) of acetic acid were added in a reaction vessel, and the reaction was carried out at 40° C. for 1 hour, at 70° C. for 1 hour and 100° C. for 2 hours. After the reaction, 40 g of cyclohexanone was further added and the reaction was carried out at 130° C. for 2 hours.

After the reaction, the mixture was cooled to return to room temperature, 30 g of pure water was added, washing with water was repeated twice, cyclohexanone was removed from the obtained organic layer using an evaporator, and 50 g of polysiloxane compound 3 (yield 100%) was obtained. The weight average molecular weight Mw measured by GPC was 1,600.

### Synthesis Example 5

Synthesis of Polysiloxane Compound 4 (HFA-Si silicate 40=1/9 Composition (Molar Ratio))

2.03 g (5 mmol) of HFA-Si, 1.11 g (62 mmol) of pure water, and 0.15 g (2.5 mmol) of acetic acid was added in a 50 mL flask, the mixture was heated to 40° C., and the mixture was stirred for 1 hour. After that, 6.70 g (45 mmol [converted to SiO₂ contained in silicate 40. (Silicate 40 itself is about 9 mmol as a pentamer)]) of silicate 40 (average pentamer, manufactured by Tama Chemicals Co., Ltd.) and 5.0 g of ethanol was added, and the mixture was stirred at 80° C. for 4 hours. No insoluble matter was generated during stirring, and the reaction solution was in a solution state.

After stirring, PGMEA was added, and water, acetic acid, a solvent and by-produced ethanol and a part of PGMEA were distilled using a rotary evaporator while reducing the pressure at 60° C., and filtered under reduced pressure to obtain a solution of 16 g of polysiloxane compound 4 having a solid content concentration of 30% by mass was obtained. The weight average molecular weight Mw measured by GPC was 3,050.

### Synthesis Example 6

### Synthesis of Polysiloxane Compound 5 (HFA-Si/silicate 40=2/8 Composition (Molar Ratio))

3.25 g (8 mmol) of HFA-Si, 1.81 g (101 mmol) of pure water, and 0.12 g (2.0 mmol) of acetic acid was added in a 50 mL flask, the mixture was heated to 40° C., and the mixture was stirred for 1 hour. After that, 4.77 g (32 mmol [converted to SiO₂ contained in silicate 40. (Silicate 40 itself is about 6.4 mmol as a pentamer)]) of silicate 40 (average pentamer, manufactured by Tama Chemicals Co., Ltd.), and 4.81 g of ethanol was added, and the mixture was stirred at 75° C. for 4 hours. No insoluble matter was generated during stirring, and the reaction solution was in a solution state.

After stirring, PGMEA was added, and water, acetic acid, a solvent and by-produced ethanol and a part of PGMEA were distilled using a rotary evaporator while reducing the pressure at 60° C., and filtered under reduced pressure to obtain a solution of 17 g of polysiloxane compound 5 having a solid content concentration of 30% by mass was obtained. The weight average molecular weight Mw measured by GPC was 3,000.

### Synthesis Example 7

### Synthesis of Polysiloxane Compound 6 (HFA-Si/Ph-Si/KBM-303/KBM-5103=1/7/1/1 Composition (Molar Ratio))

5.0 g (11.9 mmol) of HFA-Si, 0.0 g (83.3 mmol) of Ph-Si 2, KBM-303 2.9 g (11.9 mmol), KBM-5103 2.8 g (11.9 mmol) of KBM-5103, 6.7 g (375 mmol of pure water, 0.8 g (3.6 mmol) of acetic acid were added in a reaction vessel, and the reaction was carried out at 40° C. for 1 hour, 70° C. for 1 hour, and 100° C. for 4 hours.

After the reaction, the mixture was cooled to return to room temperature, 75 g of cyclohexanone and 25 g of pure water were added, and washing with water was repeated twice. Cyclohexanone was distilled from the obtained organic layer using an evaporator, and 46.5 g of polysiloxane compound 6 (yield 100%) having a solid content concentration of 50% by mass was obtained. The weight average molecular weight Mw measured by GPC was 2,460.

### Synthesis Example 8

### Synthesis of Polysiloxane Compound 7 (HFA-Si/Ph-Si/KBM-303/KBM-5103=1/7/1/1 Composition (Molar Ratio))

5.0 g (11.9 mmol) of HFA-Si, 20.0 g (83.3 mmol) of Ph-Si, 2.9 g (11.9 mmol) of KBM-303, 2.8 g (11.9 mmol) of KBM-5103, 6.7 g (375 mmol) of pure water, and 0.8 g (3.6 mmol) of acetic acid were added in a reaction vessel, and the mixture was reacted at 40° C. for 1 hour and at 75° C. for 6 hours.

After the reaction, the mixture was cooled to return to room temperature, 40 g of diisopropyl ether and 30 g of pure water were added, washing with water was repeated twice, 20 g of PGMEA was added to the obtained organic layer, and diisopropyl ether was distilled using an evaporator. 38.8 g of polysiloxane compound 7 (yield 100%) having a solid content concentration of 65% by mass was obtained. The weight average molecular weight Mw measured by GPC was 1,000.

### Synthesis Example 9

### Synthesis of Polysiloxane Compound 8 (HFA-Si/Ph-Si/KBM-303/KBM-503=1/7/1/1 Composition (Molar Ratio))

5.0 g (11.9 mmol) of HFA-Si, 20.0 g (83.3 mmol) of Ph-Si, 2.9 g (11.9 mmol) of KBM-303, 3.1 g (11.9 mmol) of KBM-503, 6.7 g (375 mmol) of pure water, and 0.8 g (3.6 mmol) of acetic acid were added, and the mixture was reacted at 40° C. for 1 hour and at 75° C. for 20 hours.

After the reaction, the mixture was cooled to return to room temperature, 30 g of diisopropyl ether and 30 g of pure water were added, washing with water was repeated twice, 20 g of PGMEA was added to the obtained organic layer, and diisopropyl ether was distilled using an evaporator. 46.5 g of polysiloxane compound 8 (yield 100%) having a solid content concentration of 66% by mass was obtained. The weight average molecular weight Mw measured by GPC was 1,180.

### Negative Patterning Test

### Example 1

2 g of the polysiloxane compound 1 (HFA-Si/Ph-Si=1/9 composition) obtained in Synthesis Example 2 was weighed, and 4 g of PGMEA and 0.04 g of CPI-200K (manufactured by San-Apro Co., Ltd.), which is a photoacid generator, were added to prepare a 33 wt % photosensitive resin composition (weight average molecular weight Mw=1,500 as measured by GPC).

### Example 2

2 g of the polysiloxane compound 3 (HFA-Si/Ph-Si/KBM-303=1/8/1 composition) obtained in Synthesis Example 4 was weighed, and 4 g of PGMEA and 0.04 g of CPI-200K (manufactured by San-Apro Co., Ltd.), which is a photoacid generator, were added to prepare a 33 wt % photosensitive resin composition (weight average molecular weight Mw=1,600 as measured by GPC).

### Example 3

3 g of the solution of the polysiloxane compound 4 (HFA-Si/silicate 40=1/9 composition) obtained in Synthesis Example 5 was weighed, and CPI- 200K (manufactured by San-Apro Co., Ltd.), which is a photoacid generator, were added to prepare a 30 wt % photosensitive resin composition.

### Example 4

3 g of the solution of the polysiloxane compound 5 (HFA-Si/silicate 40 =2/8 composition) obtained in Synthesis Example 6 was weighed, and CPI-200K (manufactured by San-Apro Co., Ltd.), which is a photoacid generator, were added to prepare a 30 wt % photosensitive resin composition.

### Example 5

10 g of the solution of the polysiloxane compound 6 (HFA-Si/Ph-Si/KBM-303/KBM-5103=1/7/1/1 composition) obtained in Synthesis Example 7 was weighed, and 0.03 g of Irgacure 290 (manufactured by BASF), which is an acid generator, was added to prepare a 50 wt % photosensitive resin composition.

### Example 6

10 g of the solution of the polysiloxane compound 7 (HFA-Si/Ph-Si/KBM-303/KBM-5103=1/7/1/1 composition) obtained in Synthesis Example 8 was weighed, and 0.8 g of PGMEA and 0.03 g of Irgacure 290 (manufactured by BASF), which is a photoacid generator, were added to prepare a 60 wt % photosensitive resin composition.

### Example 7

9.5 g of the solution of the polysiloxane compound 8 (HFA-Si/Ph-Si/KBM-303/KBM-503=1/7/1/1 composition) obtained in Synthesis Example 9 was weighed, and 0.8 g of PGMEA and 0.03 g of Irgacure 290 (manufactured by BASF), which is a photoacid generator, were added to prepare a 60 wt % photosensitive resin composition.

### Comparative Example 1

2 g of the polysiloxane compound 1 (HFA-Si/Ph-Si=1/9 composition) obtained in Synthesis Example 2 was weighed, 4 g of PGMEA and a naphthoquinone diazide compound (TKF-515; manufactured by SANBO CHEMICAL INDUSTRY CO., LTD.) which is a photosensitive compound was added to prepare a 33 wt % photosensitive resin composition.

### Comparative Example 2

2 g of the polysiloxane compound 2 obtained in Synthesis Example 3 was weighed, and 4 g of PGMEA and 0.04 g of CPI-200K (manufactured by San-Apro Co., Ltd.) were added to prepare a 33 wt % photosensitive resin composition.

### Development Test

The photosensitive resin compositions obtained in Examples 1 to 5 and Comparative Examples 1 and 2 were applied on a silicon wafer manufactured by SUMCO Corporation and having a diameter of 4 inches and a thickness of 525 μm by spin-coating (rotation speed 500 rpm). Then, the silicon wafer was heat-treated on a hot plate at 100° C. for 3 minutes to obtain a photosensitive resin film having a film thickness of 2 to 10 μm.

The obtained photosensitive resin film was irradiated with light from a high-pressure mercury lamp of 108 mJ/cm² (wavelength 365 nm) through a photomask using an exposure apparatus. Then, the obtained photosensitive resin film was heat-treated at 100° C. for 1 minute on a hot plate. After that, development was carried out by immersing in a 2.38 mass % TMAH aqueous solution for 1 minute, and then washing was carried out by immersing in pure water for 30 seconds. After washing, firing was carried out in an oven at 230° C. for 1 hour in air to obtain a patterned cured film.

The photosensitive resin compositions obtained in Examples 6 and 7 were applied onto a similar silicon wafer by spin coating (rotation speed 400 rpm). Then, the silicon wafer was heat-treated on a hot plate at 100° C. for 1 minute to obtain a photosensitive resin film having a film thickness of 20 μm.

The obtained photosensitive resin film was irradiated with light from a high-pressure mercury lamp of 112.5 mJ/cm² (wavelength 365 nm) through a photomask using an exposure apparatus. Then, it was heat-treated on a hot plate at 100° C. for 30 seconds. After that, development was carried out by immersing in a 2.38 mass % TMAH aqueous solution for 80 seconds, and then washing was carried out by immersing in pure water for 60 seconds. After washing, bleaching exposure was performed at 560 mJ/cm² without using a photomask. After the bleaching exposure, the film was fired on a hot plate at 150° C. for 5 minutes in air to obtain a patterned cured film having a film thickness of 20 μm.

As a result of confirming the obtained patterned cured film with an optical microscope, the photosensitive resin compositions of Examples 1 to 7 were negative type patterned cured films, but the photosensitive resin compositions of Comparative Examples 1 and 2 were positive patterned cured film.

### Evaluation of Various Physical Properties

The transparency and heat resistance of the patterned cured film were evaluated by the following methods. In each evaluation, for the purpose of facilitating the measurement, a cured film without a pattern (hereinafter, simply referred to as “cured film”) was prepared and various measurements were performed.

### Comparative Example 3

2 g of the polysiloxane compound 3 (HFA-Si/Ph-Si/KBM-303=1/8/1 composition) obtained in Synthesis Example 4, 4 g of PGMEA, and 0.5 g of a naphthoquinone diazide compound (TKF-515; manufactured by SANBO CHEMICAL INDUSTRY CO., LTD.) which is a photosensitive compound was added to prepare a 33 wt % photosensitive resin composition.

### Transparency Evaluation

The photosensitive resin compositions obtained in Example 2 and Comparative Example 3 were applied on a glass substrate (soda lime glass) having a diameter of 4 inches by spin coating (rotation speed 500 rpm). Then, the glass substrate was heat-treated on a hot plate at 100° C. for 3 minutes to obtain a photosensitive resin film having a film thickness of 2 to 3 μm.

The obtained photosensitive resin film was irradiated with light from a high-pressure mercury lamp of 500 mJ/cm² (wavelength 365 nm) using an exposure apparatus. Then, the film was fired in an oven at 230° C. for 1 hour in air to obtain a cured film having a film thickness of 2 to 3 μm (cured film 1 from Example 2 and cured film 2 from Comparative Example 3).

The photosensitive resin composition obtained in Example 5 was applied onto a glass substrate (soda lime glass) having a diameter of 4 inches by spin coating (rotation speed 500 rpm). Then, the glass substrate was heat-treated on a hot plate at 100° C. for 30 seconds to obtain a photosensitive resin film having a film thickness of 8 μm.

The obtained photosensitive resin film was irradiated with light from a high-pressure mercury lamp of 70 mJ/cm² (wavelength 365 nm) using an exposure apparatus. Then, the obtained photosensitive resin film was heat-treated on a hot plate at 100° C. for 30 seconds. After that, it was immersed in a 2.38 mass % TMAH aqueous solution for 60 seconds, and then immersed in pure water for 60 seconds for washing. After washing, bleaching exposure was performed at 560 mJ/cm² without using a photomask. After the bleaching exposure, firing was carried out in an oven at 230° C. for 1 hour in air to obtain a cured film 3 having a film thickness of 8 μm.

The photosensitive resin composition obtained in Example 7 was applied onto a glass substrate (soda lime glass) having a diameter of 4 inches by spin coating (rotation speed 400 rpm). Then, the glass substrate was heat-treated on a hot plate at 100° C. for 1 minute to obtain a photosensitive resin film having a film thickness of 19 μm.

The obtained photosensitive resin film was irradiated with light from a high-pressure mercury lamp of 112.5 mJ/cm² (wavelength 365 nm) using an exposure apparatus. Then, the obtained photosensitive resin film was heat-treated on a hot plate at 100° C. for 30 seconds. After that, it was immersed in a 2.38 mass % TMAH aqueous solution for 80 seconds, and then immersed in pure water for 60 seconds for washing. After washing, bleaching exposure was performed at 560 mJ/cm² without using a photomask. After the bleaching exposure, firing was carried out on a hot plate at 150° C. for 5 minutes in air to obtain a cured film 4 having a film thickness of 19 μm.

Further, a film before firing is formed by the same method as the cured film 4 until the bleaching exposure, and after the bleaching exposure, firing was carried out in an oven at 230° C. for 1 hour in air to obtain a cured film 5 having a thickness of 19 μm.

After subtracting the transmittance of the glass substrate as a blank, the light transmittance (400 nm, 350 nm, 2 μm conversion) of the obtained cured films 1 to 5 was measured, and the obtained results are shown in Table 1. As shown in Table 1, It was found that the transparency of the cured films 1 and 3 to 5 obtained by using the photosensitive resin compositions of Examples 2, 5 and 7 at any wavelength was higher than that of the cured film 2 obtained by using the photosensitive resin composition of Comparative Example 3.

TABLE 1

| Photosensitive resin | | Transparency | Transparency |
|---|---|---|---|
| composition | Cured film | (400 nm) | (350 nm) |
| Example 2 | 1 | 99% | 96% |
| Example 5 | 3 | 99% | 97% |
| Example 7 | 4 | 99% | 96% |
| Example 7 | 5 | 98% | 94% |
| Comparative Example 3 | 2 | 96% | 89% |

### Heat Resistance Evaluation 1

The cured films 1, 2, 3, and 5 prepared for the above transparency evaluation were heated in an oven at 300° C. for 1 hour in air. Table 2 shows the results of measuring the transmittance (400 nm, 350 nm) before and after heating. As shown in Table 2, the cured film 2 obtained by using the photosensitive resin composition of Comparative Example 3 had a larger amount of decrease in transmittance after heating than the cured films 1, 3 and 5 obtained by using the photosensitive resin compositions of Examples 2, 5 and 7.

TABLE 2

| | | Transparency | | Transparency | |
|---|---|---|---|---|---|
| | | (400 nm) | | (350 nm) | |
| Photosensitive resin | | Before | After | Before | After |
| composition | Cured film | heating | heating | heating | heating |
| Example 2 | 1 | 99% | 99% | 96% | 96% |
| Example 5 | 3 | 99% | 96% | 97% | 91% |
| Example 7 | 5 | 98% | 95% | 94% | 88% |
| Comparative Example 3 | 2 | 96% | 89% | 89% | 68% |

From the above, the cured films 1, 3 and 5 obtained by using the photosensitive resin compositions of Examples 2, 5 and 7 had a smaller decrease in transmittance due to heating and are more heat resistance than the cured films 2 of Comparative Example 3.

### Heat Resistance Evaluation 2

Table 3 shows the results of measuring the film thickness before and after heating in the same manner. As shown in Table 3, the cured film 2 obtained by using the photosensitive resin composition of Comparative Example 3 had a larger decrease in the film thickness by heating than the cured film 1 obtained by using the photosensitive resin composition of Example 2.

TABLE 3

| Photosensitive resin | | Film thickness | Film thickness |
|---|---|---|---|
| composition | Cured film | before heating | after heating |
| Example 2 | 1 | 2.8 μm | 2.7 μm |
| Comparative Example 3 | 2 | 2.7 μm | 2.4 μm |

From the above, the cured film obtained by using the photosensitive resin composition of Example 2 was a cured film having a smaller decrease in the film thickness due to heating and an excellent heat resistance.

### Molecular Weight Increase Rate After Exposure

### Example 8

The photosensitive resin composition (weight average molecular weight=1,600) obtained in Example 1 was applied on a silicon wafer manufactured by SUMCO Corporation with a diameter of 4 inches and a thickness of 525 μm by spin coating (rotational speed 500 rpm). Then, the silicon wafer was heat-treated on a hot plate at 100° C. for 3 minutes to obtain a photosensitive resin film having a film thickness of 2 to 3 μm.

The obtained photosensitive resin film was irradiated with light from a high-pressure mercury lamp of 560 mJ/cm² (wavelength 365 nm) using an exposure apparatus. Then, the obtained photosensitive resin film was heat-treated on a hot plate at 100° C. for 1 minute. After that, the membrane was dissolved in tetrahydrofuran and measured by GPC. As a result, the weight average molecular weight Mw was 2,600. The rate of increase in molecular weight with respect to the original photosensitive resin composition was 0.73.

### Example 9

The photosensitive resin composition (weight average molecular weight=3,100) obtained in Example 2 was applied on a silicon wafer manufactured by SUMCO Corporation and having a diameter of 4 inches and a thickness of 525 μm by spin coated (rotation speed 500 rpm). Then, the silicon wafer was heat-treated on a hot plate at 100° C. for 3 minutes to obtain a photosensitive resin film having a film thickness of 2 to 3 μm.

The obtained photosensitive resin film was irradiated with light from a high-pressure mercury lamp of 560 mJ/cm² (wavelength 365 nm) using an exposure apparatus. Then, the obtained photosensitive resin film was heat-treated at 100° C. for 1 minute on a hot plate. After that, the membrane was dissolved in tetrahydrofuran and measured by GPC. As a result, the weight average molecular weight Mw was 14,000. The rate of increase in molecular weight with respect to the original photosensitive resin composition was 7.7.

### Evaluation of Chemical Resistance and Adhesion of Cured Film

### Example 10

The photosensitive resin composition obtained in Example 6 was applied on a silicon wafer having a diameter of 4 inches by spin coating (rotation speed 400 rpm). Then, the silicon wafer was heat-treated on a hot plate at 100° C. for 1 minute to obtain a photosensitive resin film having a film thickness of 18 μm.

The obtained photosensitive resin film was irradiated with light from a high-pressure mercury lamp of 112.5 mJ/cm² (wavelength 365 nm) using an exposure apparatus. Then, the obtained photosensitive resin film was heat-treated on a hot plate at 100° C. for 30 seconds. After that, it was immersed in a 2.38 mass % TMAH aqueous solution for 80 seconds, and then immersed in pure water for 60 seconds for washing. After washing, bleaching exposure was performed at 560 mJ/cm² without using a photomask. After the bleaching exposure, firing was carried out on a hot plate at 150° C. for 5 minutes in air to obtain a cured film 6 having a film thickness of 18 μm.

### Evaluation of Resistance to Organic Solvent

The cured films 1, 3, 4, and 6 obtained above were each immersed in organic solvents (N-methyl-2-pyrrolidone (NMP), isopropyl alcohol (IPA), PGMEA, propylene glycol monomethyl ether (PGME) and acetone) at 40° C. for 7 minutes. Then, these were dried on a hot plate at 100° C. for 5 minutes. The cured film after drying was visually observed and the film thickness was measured. The results are shown in Table 4.

### Evaluation of Resistance to Acidic Solution

The cured films 1, 3, 4, and 6 obtained above were each immersed in a mixed aqueous solution of concentrated hydrochloric acid: 98% nitric acid: water (50: 7.5: 42.5, mass ratio) at room temperature for 1 minute. The cured films after the immersion treatment were visually observed and the film thickness was measured. The results are shown in Table 5 (the mixed solution is described as “acid” in the table).

### Evaluation of Resistance to Basic Solution

The cured films 1, 3, 4, and 6 obtained above were each immersed in a mixed aqueous solution of dimethylsulfoxide : monoethanolamine : water (1:1:2, mass ratio), a mixed aqueous solution of dimethylsulfoxide: monoethanolamine (1:1, mass ratio), 2.38 mass % TMAH aqueous solution, and 1 mass % sodium carbonate (Na₂CO₃) aqueous solution for 1 minute at room temperature. The cured films after the immersion treatment were visually observed and the film thickness was measured. The results are shown in Table 5 (in the table, the mixed aqueous solution is described as “base (water)” and the mixed solution is described as “base (organic)”).

TABLE 4

| Photosensitive | | | | | | | |
|---|---|---|---|---|---|---|---|
| resin | Cured | | | | | | |
| composition | film | | NMP | IPA | PGMEA | PGME | Acetone |
| Example 2 | 1 | Change | +4 | 0 | +2 | +1 | 0 |
| | | rate (%) | | | | | |
| | | Evaluation | ⊚ | ⊚ | ⊚ | ⊚ | ⊚ |
| Example 5 | 3 | Change | +3 | +1 | +2 | +1 | 0 |
| | | rate (%) | | | | | |
| | | Evaluation | ⊚ | ⊚ | ⊚ | ⊚ | ⊚ |
| Example 6 | 6 | Change | +4 | 0 | +2 | +1 | 0 |
| | | rate (%) | | | | | |
| | | Evaluation | ⊚ | ⊚ | ⊚ | ⊚ | ⊚ |
| Example 7 | 4 | Change | +3 | +3 | +3 | +1 | 0 |
| | | rate (%) | | | | | |
| | | Evaluation | ⊚ | ⊚ | ⊚ | ⊚ | ⊚ |

Change rate (%): 100 × ((film thickness after immersion treatment) − (film thickness before immersion treatment))/(film thickness before immersion treatment)
⊚: Change rate is within ±5%

TABLE 5

| Photosensitive | | | | | | | |
|---|---|---|---|---|---|---|---|
| resin | Cured | | | Base | Base | | |
| composition | film | | Acid | (Water) | (Organic) | TMAH | Na₂CO₃ |
| Example 2 | 1 | Change | 0 | 0 | 0 | 0 | 0 |
| | | rate (%) | | | | | |
| | | Evaluation | ⊚ | ⊚ | ⊚ | ⊚ | ⊚ |
| Example 5 | 3 | Change | 0 | 0 | 0 | 0 | 0 |
| | | rate (%) | | | | | |
| | | Evaluation | ⊚ | ⊚ | ⊚ | ⊚ | ⊚ |
| Example 6 | 6 | Change | 0 | 0 | +4 | 0 | 0 |
| | | rate (%) | | | | | |
| | | Evaluation | ⊚ | ⊚ | ⊚ | ⊚ | ⊚ |
| Example 7 | 4 | Change | 0 | 0 | +1 | 0 | 0 |
| | | rate (%) | | | | | |
| | | Evaluation | ⊚ | ⊚ | ⊚ | ⊚ | ⊚ |

Change rate (%): 100 × ((film thickness after immersion treatment) − (film thickness before immersion treatment))/(film thickness before immersion treatment)
⊚: Change rate is within ±5%

From the above, it was confirmed that the change rate of the cured films 1, 3, 6 and 4 was within ±5%, and that the cured films were resistant to organic solvents, acidic solutions and basic solutions. Further, the chemical resistance of the cured films 6 and 4 obtained by firing at 150° C. was also confirmed, and the cured films 6 and 4 could be cured at 150° C.

### Evaluation of Adhesion

The photosensitive resin composition obtained in Examples 2, 5 and 7 were applied onto each substrate (silicon wafer, silicon nitride substrate, glass substrate, polyimide (Kapton) substrate, polyethylene terephthalate substrate, polycarbonate substrate, polyethylene naphthalate substrate, which have a diameter of 4 inches) by spin coating (rotation speed 500 rpm). Then, each of the above substrates was heat-treated on a hot plate at 100° C. for 3 minutes to obtain a photosensitive resin film having a film thickness of 1 to 19 μm.

The obtained photosensitive resin films were irradiated with light from a high-pressure mercury lamp of 500 mJ/cm² (wavelength 365 nm) using an exposure apparatus. Then, the obtained photosensitive resin films were fired in an oven at 230° C. for 1 hour in the atmosphere to obtain each cured film having a film thickness of 1 to 19 μm (similar to the cured films 1, 3 and 4 described above).

The adhesion of the cured film to each substrate was evaluated in accordance with JIS K 5600-5-6 (cross-cut method) for the cured film on each substrate obtained above.

### (Test 1)

Specifically, after forming 25 squares of a 1 mm square grid on the cured film with a cutter knife, it was held in an environment of 85° C. and 85% relative humidity for 7 days. Cellophane tape was attached to the lattice portion of the obtained cured film, and then peeled off for visual confirmation. As a result, it was found that no peeling was observed on all the substrates (classification 0), and good adhesion was exhibited.

### (Test 2)

In addition, the adhesion was evaluated by the following method in accordance with JIS K 5600-5-6 (cross-cut method) in the same manner as above.

Specifically, 25 squares having a size of 1 mm square were formed on the cured film with a cutter knife, and then it was held in an environment of a pressure cooker test (121° C., 100% relative humidity, 2 atm) for 1 day. Cellophane tape was attached to the lattice portion of the obtained cured film, and then peeled off for visual confirmation. As a result, it was found that no peeling was observed on all the substrates (classification 0), and good adhesion was exhibited.

The negative photosensitive resin composition is useful as a photosensitive material capable of forming a negative patterning. The obtained photosensitive resin film is soluble in an alkaline developing solution and has patterning performance, and the cured film is excellent in heat resistance and transparency. Therefore, it can be used as a protective film for semiconductors, a flattening material, a microlens material, an insulating protective film for a touch panel, a TFT flattening material for a liquid crystal display, a core or clad forming material for an optical waveguide, an electron beam resist, a multilayer resist intermediate film, an underlayer film, an antireflection film and the like. Further, when used for an optical member such as a display or an image sensor, a known refractive index adjusting agent may be mixed.

Further, when the photoinduced curing accelerator is a photoacid generator and/or a photobase generator, a patterned cured film can be obtained by heat treatment at a low temperature of 200° C. or lower, so that the negative photosensitive resin composition can be used as various optical members and constituent members such as flexible displays using a plastic substrate or a resin film, organic semiconductors containing organic materials in the constituent members, and organic solar cells.

According to the present invention, a negative photosensitive resin composition based on a polysiloxane compound is provided.

1. A negative photosensitive resin composition comprising:
(A) a polysiloxane compound containing a first structural unit represented by a following general formula (1);
(B) a photoinduced curing accelerator; and
(C) a solvent,
[(R^{x})_{b}R¹ₘSiO_{n/2}] (1)
wherein, in the general formula (1), R^{x} is a monovalent group represented by a following general formula (1a), 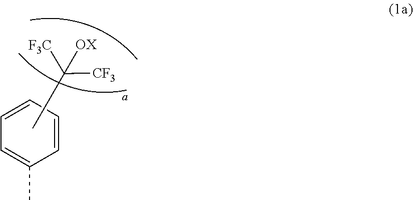
R¹ is a substituent selected from a group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms,
b is a number of 1 or more and 3 or less, m is a number of 0 or more and less than 3, n is a number of more than 0 and 3 or less, b+m+n=4,
when there are a plurality of R^{x} and R¹, R^{x} and R¹ are independently selected from any of the substituents, and
in the general formula (1a), X is a hydrogen atom, a is a number of 1 or more and 5 or less, and a broken line represents a bond.

2. The negative photosensitive resin composition according to claim 1, wherein the group represented by the general formula (1a) is any of the groups represented by following general formulas (1aa) to (1ad), 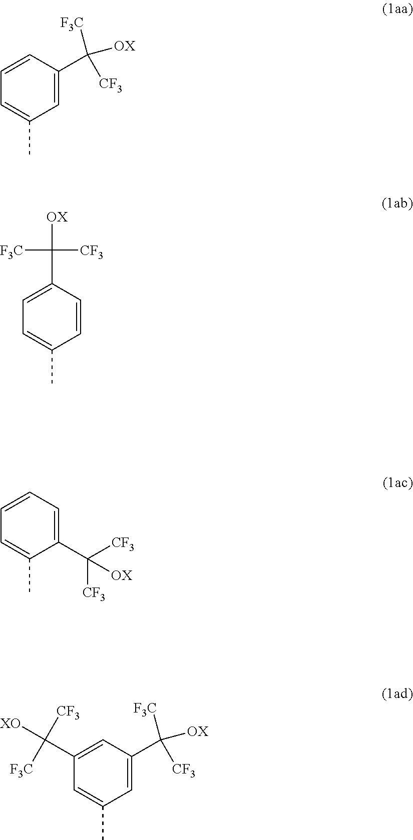
wherein in the general formulas (1aa) to (1ad), broken line represents a bond.

3. The negative photosensitive resin composition according to claim 1, wherein the first structural unit is a single structural unit.

4. The negative photosensitive resin composition according to claim 1, wherein the photoinduced curing accelerator is composed of a photoacid generator and/or a photobase generator.

5. The negative photosensitive resin composition according to claim 1, wherein the solvent includes at least one compound selected from a group consisting of propylene glycol monomethyl ether acetate, propylene glycol monomethyl ether, cyclohexanone, ethyl lactate, γ-butyrolactone, diacetone alcohol, diglyme, methyl isobutyl ketone, 3-methoxybutyl acetate, 2-heptanone, N,N-dimethylformamide, N,N-dimethylacetamide, N-methylpyrrolidone, glycols and glycol ethers, and glycol ether esters.

6. The negative photosensitive resin composition according to claim 1 wherein the polysiloxane compound contains a second structural unit represented by a following general formula (2) and/or a third structural unit represented by a following general formula (3),
[(R^{y})_{c}R²ₚSiO_{q/2}] (2)
[(R^{W})ₜSiO_{u/2}] (3)
wherein in the general formula (2), R^{y} is a substituent selected from monovalent organic groups having 1 or more and 30 or less carbon atoms containing any of an epoxy group, an oxetane group, an acryloyl group, a methacryloyl group or a lactone group,
R² is a substituent selected from a group consisting of a hydrogen atom, an alkyl group having 1 or more and 3 or less carbon atoms, a phenyl group, a hydroxy group, alkoxy groups having 1 or more and 3 or less carbon atoms and fluoroalkyl groups having 1 or more and 3 or less carbon atoms,
c is a number of 1 or more and 3 or less, p is a number of 0 or more and less than 3, and q is more than 0 and 3 or less, and c+p+q=4,
when there are a plurality of R^{y} and R², R^{y} and R² are independently selected from any of the substituents,
in the general formula (3), R^{W} is a substituent selected from a group consisting of a halogen group, an alkoxy group and a hydroxy group, and
t is a number of 0 or more and less than 4, u is a number of more than 0 and 4 or less, and t+u=4.

7. The negative photosensitive resin composition according to claim 6, wherein the monovalent organic group R^{y} is a group represented by a following general formulas (2a), (2b), (2c), (3a), or (4a), 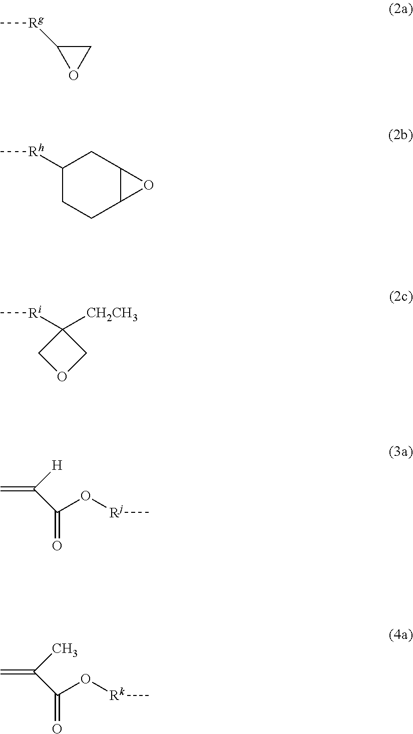
wherein in the general formula (2a), (2b), (2c), (3a), or (4a), R^{g}, R^{h}, Rⁱ, R^{j} and R^{k} each independently represent a divalent linking group, and a broken line represents a bond.

8. The negative photosensitive resin composition according to claim 6, wherein the monovalent organic group R^{y} is a substituent selected from monovalent organic groups having 1 to 30 carbon atoms including any of an epoxy group, an acryloyl group, and a methacryloyl group.

9. The negative photosensitive resin composition according to claim 1, wherein the polysiloxane compound has a weight average molecular weight of 500 to 50,000.

10. The negative photosensitive resin composition according to claim 1, wherein in a weight average molecular weight (Mw₁) of the negative photosensitive resin composition and a weight average molecular weight (Mw₂) of a film obtained by applying the negative photosensitive resin composition to a substrate, exposing to light at 365 nm at 560 mJ/cm², and curing by heating at 100° C. for 1 minute, a rate of increase in molecular weight represented by (Mw₂-Mw₁)/Mw₁ is 0.50 or more.

11. A pattern structure comprising: a first structure formed on a substrate and containing (A) a polysiloxane compound containing a first structural unit represented by a following general formula (1A) and (B) a modified product of a photoinduced curing accelerator; and a second structure containing a component different from the first structure or a void
[(R^{x1})_{b1}R¹¹ₘ₁SiO_{n1/2}] (1A)
wherein in the general formula (1A), R^{x1} is a monovalent group represented by following general formula (1Aa), 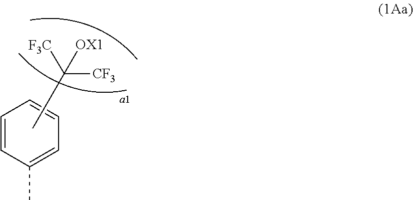
R¹¹ is a substituent selected from a group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms,
b1 is a number of 1 or more and 3 or less, ml is a number of 0 or more and less than 3, n1 is a number of more than 0 and 3 or less, b1+m1+n1=4,
when there are a plurality of R^{x1} and R¹¹, R^{x1} and R¹¹ are independently selected from any of the substituent, and
in the general formula (1Aa), X1 is a hydrogen atom or a bond site with Si or C contained in a structural unit different from the first structural unit represented by the general formula (1A), al is a number of 1 or more and 5 or less, and a broken line represents a bond.

12. The pattern structure according to claim 11, wherein the polysiloxane compound has a weight average molecular weight of 750 to 500,000.

13. A method for producing a patterned cured film formed on a substrate comprising: applying a negative photosensitive resin composition including (A) a polysiloxane compound containing a first structural unit represented by a following general formula (1), (B) a photoinduced curing accelerator, and (C) a solvent to the substrate to form a photosensitive resin film,
exposing the photosensitive resin film through a photomask, and
dissolving an unexposed portion of the photosensitive resin film with an alkaline solution
[(Rx)bR1mSiOn/2] (1)
wherein in the general formula (1), R^{x} is a monovalent group represented by following general formula (1a),
R¹ is a substituent selected from a group consisting of a hydrogen atom, an alkyl group having 1 to 3 carbon atoms, a phenyl group, a hydroxy group, an alkoxy group having 1 to 3 carbon atoms and a fluoroalkyl group having 1 to 3 carbon atoms,
b is a number of 1 or more and 3 or less, m is a number of 0 or more and less than 3, n is a number of more than 0 and 3 or less, b+m+n=4,
when there are a plurality of R^{x} and R¹, R^{x} and R¹ are independently selected from any of the substituent, and
in the general formula (1a), X is a hydrogen atom, a is a number of 1 or more and 5 or less, and a broken line represents a bond.

14. The method for producing the patterned cured film according to claim 13 further comprising: heating a patterned resin film obtained by dissolving the unexposed portion of the photosensitive resin film with the alkaline solution, thereby curing the patterned resin film to obtain the patterned cured film.

15. The method for producing the patterned cured film according to claim 13, wherein the photosensitive resin film is exposed through the photomask by exposing to light having a wavelength of 1 nm to 600 nm.

16. The method for producing the patterned cured film according to claim 13 further comprising: the exposed photosensitive resin film is heated, after exposing the photosensitive resin film through the photomask, and dissolving the unexposed portion of the heated photosensitive resin film with the alkaline solution.
